(19) United States
(12) Patent Application Publication
(10) Pub. No.: US 2017/0093175 A1
(43) Pub. Date: Mar. 30, 2017

(54) METHODS AND APPARATUS FOR WIRELESS CHARGING

(71) Applicant: Intel Corporation, Santa Clara, CA (US)

(72) Inventors: Lei Shao, Sunnyvale, CA (US); Xintian E. Lin, Mountain View, CA (US); Longcheng B. Zhu, Shanghai (CN); Gary G. Li, Beaverton, OR (US)

(21) Appl. No.: 14/866,163

(22) Filed: Sep. 25, 2015

(51) Int. Cl. H02J 7/00; G01R 31/36; H02J 7/02

(52) U.S. Cl. CPC H02J 7/007; H02J 7/025; H02J 7/0052; G01R 31/3648; H02J 2007/0001; H02J 2007/0096

(57) ABSTRACT

A disclosed example method to detect eligibility for wireless charging at a power transmitting unit involves receiving a measured charging pattern from a power receiving unit that is in communication with the power transmitting unit. When the measured charging pattern does not match a reference charging pattern used to modulate an electrical current at a transmitter resonator of the power transmitting unit, the power receiving unit is not eligible for wireless charging by the power transmitting unit. When the measured charging pattern does match the reference charging pattern, the power receiving unit is eligible for wireless charging by the power transmitting unit.

### FIELD OF THE DISCLOSURE

The present disclosure relates generally to wireless communications and, more particularly, to wireless charging of wireless devices.

### BACKGROUND

Wireless devices consume significant amounts of power from batteries. To maintain operability of the wireless devices, charging is necessary at times of low battery charge. Prior techniques for charging wireless device batteries involve removing the batteries from the devices and plugging the batteries into a battery charger. Other prior techniques involve physically plugging an electrically conductive cable from the wireless device to a constantly available power source such as an alternating current (AC) power source (e.g., a wall outlet) to charge a batter installed in the wireless device. More recent techniques for charging wireless device batteries involve wireless charging. For wireless charging, the wireless device is equipped with a wireless power receiver (e.g., an inductive coil) that receives power from a wireless power station having a wireless power transmitter (e.g., another inductive coil). When the wireless device is placed in sufficient proximity to the wireless power station, the wireless power transmitter of the wireless power station transmits energy via an electromagnetic field that is received by the wireless power receiver of the wireless device. The wireless power receiver of the wireless device converts the energy received via the electromagnetic field into electrical current to charge a battery of the wireless device.

### BRIEF DESCRIPTION OF THE DRAWINGS

FIG. 1 is an example wireless charging environment having a wireless charging power transmitting unit (PTU) in wireless charging proximity to a wireless device power receiving unit (PRU) and in wireless communication proximity of numerous other PRUs.

FIG. 2 is an example communication diagram of wireless communications between the PTU and PRUs of FIG. 1 to detect cross-connection during a wireless charging process and to reduce or eliminate the effects of such cross-connection on wireless charging of the PRU.

FIG. 3 is an example PRU dynamic parameter element that the PRUs of FIGS. 1 and 2 use to send rectifier voltage measurements associated with wireless charging to the PTU of FIGS. 1 and 2.

FIG. 4 depicts components of the PTU and the PRU of FIGS. 1 and 2.

FIG. 5 depicts example flow diagrams representative of computer readable instructions that may be executed to implement the PRU and the PTU of FIGS. 1, 2, and 4 to detect cross-connection associated with wireless charging.

FIG. 6 is an example processor platform capable of executing machine readable instructions represented by an example PTU process flow diagram of FIG. 5 to implement the example PTU of FIGS. 1, 2, and 4.

FIG. 7 is an example processor platform capable of executing machine readable instructions represented by an example PRU process flow diagram of FIG. 5 to implement the example PRUs of FIGS. 1, 2, and 4.

### DETAILED DESCRIPTION

Examples disclosed herein may be used with wireless charging of battery-operated devices to detect cross-connection between a power transmitting unit (PTU) (e.g., a wireless charging station) and numerous power receiving units (PRUs) (e.g., battery-operated wireless devices) during wireless charging processes, and to reduce or eliminate the effects of such cross-connection on wireless charging of a target PRU. For example, for wireless charging, a PRU is equipped with a wireless power receiver (e.g., an inductive coil) that receives power from a PTU having a wireless power transmitter (e.g., another inductive coil). When the PRU is placed in sufficient proximity to the PTU, the wireless power transmitter of the PTU transmits power in an electromagnetic field that is received by the wireless power receiver of the PRU. The wireless power receiver of the PRU converts the power received in the electromagnetic field into electrical current to charge a battery of the PRU. To facilitate such wireless charging, the PTU and the PRU also communicate with one another using wireless communications. Although the wireless charging electromagnetic field emitted by the PTU is receivable by the PRU when the PRU is within sufficiently close proximity (e.g., within an inch, or within a few millimeters or centimeters) to the PTU, the wireless communications sent by the PTU to initiate a wireless charging process can be received by PRUs that are further from the PTU than the maximum possible distance to carry out successful wireless charging. As such, PRUs that are not within sufficiently close proximity to a PTU for successful wireless charging may still engage in communications with the PTU to erroneously initiate a wireless charging process. Such circumstances are referred to herein as cross-connection events between a PTU and non-target PRUs (e.g., PRUs that are not intended to be the targets of wireless charging).

Cross-connection by non-target PRUs that are not actual targets of wireless charging can have undesirable effects such as degrading, interrupting, and/or preventing the charging processes of actual target PRUs that are intended for wireless charging (e.g., PRUs that are intentionally placed by users within sufficiently close proximity to a PTU to undergo wireless charging of the PRUs). For example, wireless charging in high-density environments such as conference rooms or enterprise cube environments in which PRU density is high (e.g., a large number of PRUs are present), a PTU can unintentionally cross-connect to one or more non-target PRUs that is/are not within sufficiently close proximity to the PTU for wireless charging by the PTU. This significantly degrades the user experience of target PRUs that are actually intended to undergo wireless charging. Examples disclosed herein may be used to detect instances of cross-connection and substantially reduce or eliminate adverse effects of such cross-connection on wireless charging of target PRUs. An example adverse effect may include instances of a PTU overcharging a target PRU when the PTU fails to receive a charge complete message from the target PRU because the PTU is communicatively connected to a different, non-target PRU. Another example adverse effect may include that the PTU receives incorrect charging parameters from a non-target PRU and uses the incorrect charging parameters to charge a target PRU in a non-optimal manner that could undercharge the target PRU and/or damage the target PRU.

Examples disclosed herein use forward-signaling techniques to detect cross-connection between a PTU and one or more PRUs. Cross-connection refers to the unintended result of establishing communications between the PTU and a non-target PRU using out-of-band (OOB) wireless communications that are separate from inductive charging power between the PTU and a target PRU. In examples disclosed herein, the OOB wireless communications are implemented using direct, wireless peer-to-peer connections between PTUs and PRUs based on the Bluetooth® low-energy wireless protocol. However, any other wireless protocol may be used including any other direct, wireless peer-to-peer communication protocols (e.g., Wi-Fi Direct) and/or any other wireless protocols that use an intermediary access point between PTUs and PRUs (e.g., Wi-Fi). Example forward-signaling techniques disclosed herein involve the PTU modulating a current (e.g., a coil current, I_{COIL}) across its transmitting inductive coil (e.g., a transmitter (Tx) resonator) to vary power transmitted in an electromagnetic field generated by the transmitting inductive coil. This varying power of the electromagnetic field is received by a receiving inductive coil (e.g., a receiver (Rx) resonator) of a target PRU which results in voltage levels (e.g., rectifier voltage, V_{RECT}) that change over time at the receiving inductive coil. To use such current modulation for detecting cross-connection, examples disclosed herein modulate the electrical current of the Tx resonator at the PTU at particular time intervals between current levels that produce high and low voltages at the Rx resonator of the target PRU. For example, the electrical current of the Tx resonator is modulated to create a charging pattern (e.g., a reference charging pattern) of high and low voltages at the target PRU across the time intervals. In this manner, the target PRU can measure the resulting voltage levels at its Rx resonator and generate a measured charging pattern based on the high and low voltage levels across the time intervals. The measured charging pattern generated by the target PRU is representative of the reference charging pattern created by the modulated high and low electrical currents at the PTU. In examples disclosed herein, the target PRU sends the generated binary value to the PTU using an OOB wireless communication, and the PTU compares the received measured charging pattern to the reference charging pattern that it created using the modulated high and low electrical currents. When the PTU confirms that the received measured charging pattern matches its reference charging pattern, the PTU continues its wireless charging of the target PRU because the PTU has confirmed that it is actually charging a device.

For instances in which the PTU has cross-connected with a non-target PRU, the non-target PRU sends the PTU a binary value that is based on voltage levels at its Rx resonator, but the PTU detects the cross-connection because the measured charging pattern from the PRU does not match the reference charging pattern created by the PTU at its Tx resonator. That is, the non-target PRU is not within sufficiently close proximity to the PTU for the non-target PRU to receive an electromagnetic field from the PTU to affect voltage levels at the Rx resonator of the non-target PRU. As such, the voltage levels at the Rx resonator of the non-target PRU do not correspond to the modulated electrical current of the PTU. In such instances of cross-connection, the PTU stops its wireless charging process unless it receives a measured charging pattern from a PRU that does match the reference charging pattern created by the PTU at its Tx resonator (e.g., a binary value from a target PRU that is in sufficiently close proximity to the PTU for successful wireless charging).

Example forward-signaling techniques disclosed herein to modulate an electrical current at a Tx resonator of a PTU facilitate scalability and reliability. Example forward-signaling techniques disclosed herein facilitate scalability by being extendable to a significant number of PRUs without significantly increasing the amount of time needed to detect cross-connection. That is, in examples disclosed herein a PTU needs to only once create a reference charging pattern of modulated electrical current at its Tx resonator for reception by a target PRU. After modulating the reference charging pattern, the PTU can receive any number of measured charging patterns from PRUs to determine whether cross-connection exists. Since the PTU modulates its reference charging pattern once, the PTU can relatively quickly detect whether cross-connection exists based on received measured charging patterns from PRUs without needing to modulate its reference charging pattern numerous times. In contrast, backward-signaling techniques involve PRUs that generate charging patterns for detection by the PTU. In uses of such backward-signaling, as the number of PRUs increases within range of a PTU, the more charging patterns the PTU must detect to confirm whether cross-connection exists. This causes a large amount of latency due to the number of charging patterns that the PTU must detect and the time required to synchronize the PTU with each PRU to detect the charging patterns.

Example forward-signaling techniques disclosed herein also provides a high-level of reliability of cross-connection detections due to the larger amount of electrical power available to a PTU to generate reference charging patterns relative to the smaller amount of battery power available to PRUs for generating charging patterns. That is, in a backward-signaling process, a PRU's limited amount of battery power (especially during times of low battery charge) makes it challenging for a PRU to modulate its electrical current at its inductive charging coil with a sufficient range between high and low electrical current values to generate a sufficiently strong electromagnetic field that can be reliably detected by a PTU. However, the example forward-signaling techniques disclosed herein use the PTU, which is typically powered by a constantly available power source such as an AC power source, to generate the reference charging pattern. Using a constantly available power source to modulate its electrical current enables the PTU to generate sufficiently strong electromagnetic fields that are relatively easily detected with a high degree of reliability by a target PRU.

Examples disclosed herein may be used in connection with any suitable wireless charging standard including, for example, wireless charging standards from the Alliance for Wireless Power (A4WP) (e.g., the Rezence wireless charging standard), the Power Matters Alliance (PMA), the wireless power consortium (WPC) (e.g., the Qi wireless charging standard), and/or any other wireless charging standards group.

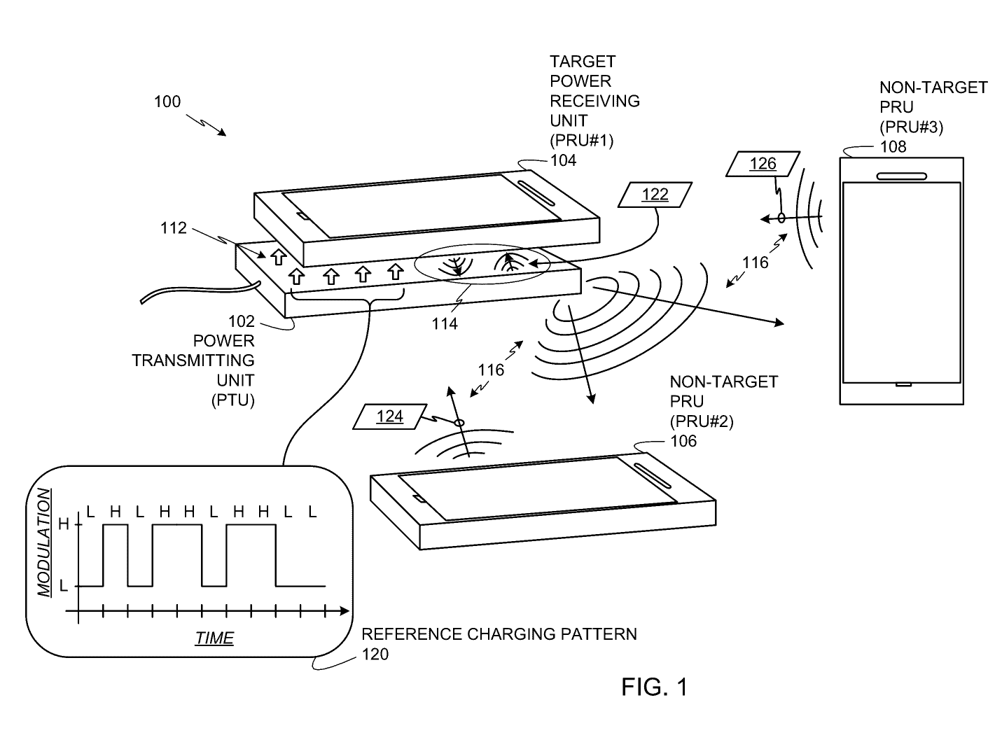

FIG. 1 is an example wireless charging environment 100 having a wireless charging power transmitting unit (PTU) 102 in wireless charging proximity to a wireless device power receiving unit (PRU) 104 (identified in the example of FIG. 1 as PRU#1) and in wireless communication proximity of numerous other PRUs including a second PRU (PRU#2) 106 and a third PRU (PRU#3) 108. In the illustrated example, the PTU 102 is a wireless charging station that charges PRUs by generating an electromagnetic field that transfers power to the PRUs when the PRUs are within sufficient proximity to the PTU 102 such that the PRUs can receive the electromagentic field and convert the electromagnetic field into power to charge batteries of the PRUs. The PRUs 104, 106, 108 of the illustrated example are battery powered devices such as wireless mobile telephones, Bluetooth devices, wearable wireless devices, phablets (e.g., tablet-sized phones), cameras, tablet computers, laptop computers, and/or any other battery-operated wireless mobile device that is capable of being wirelessly charged by the PTU 102 when placed within sufficiently close proximity to the PTU 102.

In the illustrated example, the PRU#1 104 is a target PRU 104 that is intended to undergo wireless charging by the PTU 102 (e.g., a user intentionally places the target PRU 104 within sufficiently close proximity to the PTU 102 to wirelessly charge the target PRU 104). In the illustrated example, the PRU#2 106 is a non-target PRU 106, and the PRU#3 108 is another non-target PRU 108 (e.g., the non-target PRUs 106, 108 are not placed within wireless charging proximity of the PTU 102). Although only one target PRU 104 is shown in the illustrated example of FIG. 1, examples disclosed herein may be used in connection with multiple target PRUs simultaneously. For example, the PTU 102 may be a charging mat having a large surface area or other charging structure that is capable of charging numerous target PRUs that are set on or in sufficiently close proximity to the PTU 102 (e.g., numerous target PRUs that are located within wireless charging proximity of the PTU 102).

In the illustrated example, the PTU 102 creates an electromagnetic field 112 to induce a wireless charge in the target PRU 104 to charge a battery of the target PRU 104. The example PTU 102 and the example target PRU 104 use OOB wireless communications 114 to exchange control information to initiate, manage, and end wireless charging processes during which the PTU 102 wirelessly charges the target PRU 104. In examples disclosed herein, the OOB wireless communications 114 are separate from the electromagnetic field 112. However, in other examples, the OOB wireless communications 114 may instead be in band (IB) communications exchanged using the electromagnetic field 112. In the illustrated example of FIG. 1, the non-target PRUs 106, 108 are also in communication with the PTU 102 using OOB wireless communications 116. The OOB wireless communications 114, 116 of the illustrated example are implemented using Bluetooth® low energy (BLE) communications. However, any other wireless communication protocol may be used.

In examples disclosed herein, the PTU 102 and the PRUs 104, 106, 108 use the OOB wireless communications 114 and 116 to communicate information to detect cross-connection. For example, the PTU 104 uses a reference charging pattern 120 to modulate the power transferred via the electromagnetic field 112. The reference charging pattern 120 of the illustrated example is represented by a 10-interval pattern shown as L-H-L-H-H-L-H-H-L-L (e.g., H corresponding to a high I_{COIL} electrical current level, and L corresponding to a low I_{COIL} electrical current level). By modulating the electromagnetic field 112 using the reference charging pattern 120, corresponding voltage levels (V_{RECT}) are generated at the target PRU 104 when an Rx resonator of the target PRU 104 receives the modulated electromagnetic field 112. The target PRU 104 of the illustrated example measures the voltage values (V_{RECT}) at its Rx resonator to generate a corresponding measured charging pattern 122 representative of the measured V_{RECT} voltage values. The target PRU 104 then uses the OOB wireless communications 114 to send the measured charging pattern 122 to the PTU 102. In addition, the non-target PRUs 106, 108 send the PTU 102 respective measured charging patterns 124, 126 representative of V_{RECT} voltage values measured at respective Rx resonators of the non-target PRUs 106, 108.

The PTU 102 of the illustrated example compares the measured charging patterns 122, 124, 126 received from the target PRU 104 and the non-target PRUs 106, 108 to the reference charging pattern 120 used by the PTU 102 to modulate an electrical current applied at its Tx resonator that in turn modulates the electromagnetic field 112. The example PTU 102 can then determine whether to continue a power transfer for a wireless charging process based on whether at least one of the measured charging patterns 122, 124, 126 from the PRUs 104, 106, 108 matches the reference charging pattern 120 of the PTU 102. In the illustrated example of FIG. 1, the PTU 102 detects a match between its reference charging pattern 120 and the measured charging pattern 122 from the target PRU 102 and a non-match between its reference charging pattern 120 and the measured charging patterns 124, 126 from the non-target PRUs 106, 108. Although cross-connection is present between the PTU 102 and the non-target PRUs 106, 108, at least one PRU, the target PRU 104, is an actual wireless charging target within wireless charging proximity of the PTU 102. As such, the PTU 102 continues a power transfer process to wirelessly charge the target PRU 104.

In examples in which the target PRU 104 is not within wireless charging proximity of the PTU 102, none of the measured charging patterns 122, 124, 126 received by the PTU 102 from PRUs matches the reference charging pattern 120 of the PTU 102. In such examples, the PTU 102 determines that cross-connection with non-target PRUs has erroneously initiated a power transfer for wireless charging by the PTU 102. As such, when no measured charging patterns 122, 124, 126 from PRUs match the reference charging pattern 120 of the PTU 102, the PTU 102 stops a power transfer to end a wireless charging process.

In the illustrated example, the PTU 102 uses any suitable time interval to modulate different electrical current levels applied at its Tx resonator based on corresponding portions or intervals of the reference charging pattern 120. For example, each electrical current level of the reference charging pattern 120 is represented by a corresponding high (H) or low (L) VRECT voltage level in the 10-interval pattern L-H-L-H-H-L-H-H-L-L. In some examples, each high/low level of the reference charging pattern 120 is represented by a corresponding binary bit (e.g., H=1, L=0) such that a 10-interval pattern is represented using ten bits (e.g., a 10-bit charging pattern). If the example PTU 102 uses 4 millisecond (ms) intervals for each electrical current (I_{COIL}) level modulation of the reference charging pattern 120, the PTU 102 can complete electrical current modulation based on the reference charging pattern 120 in 40 ms (e.g., 4 ms×10 electrical current modulation intervals). Alternatively, a 32-interval reference charging pattern (e.g., represented by 32 bits for the 32 intervals) would take 128 ms at a 4 ms modulation interval duration. If the PTU 102 uses a 250 ms modulation interval duration, the PTU 102 completes electrical current modulation based on the 10-interval reference charging pattern 120 in 2.5 seconds (s) (e.g., 250 ms×10 electrical current modulation intervals). In examples disclosed herein, a modulation interval duration is a length of time for which a high electrical current level or a low electrical current level is held at the Tx resonator of the PTU 102 to represent a corresponding portion or interval of the reference charging pattern 120. Selection of a time interval duration for modulating the electrical current (I_{COIL}) at the Tx resonator of the PTU 102 may be based on the minimum latency for PTUs to change between different current levels at their Tx resonators, the minimum latency for PRUs to detect changes in V_{RECT} voltage levels at their Rx resonators, and/or any other suitable characteristics.

In some examples implemented in accordance with existing wireless communication standards, the modulation interval duration for modulating the I_{COIL} electrical current at the Tx resonator of the PTU 102 may be based on an existing V_{RECT} voltage level reporting interval at which the PRUs 104, 106, 108 report V_{RECT} voltage level measurements to the PTU 102. For example, the A4WP Wireless Power Transfer System Baseline System Specification (BSS) specifies that PRUs are to report their V_{RECT} voltage level measurements to the PTU 102 every 250 ms. However, as described above, 250 ms for V_{RECT} voltage level reporting intervals may be too slow when reporting a multi-interval measured charging pattern. For faster reporting of multi-interval measured charging patterns, the PTU 102 may be configured to send a modulation interval duration value to the PRUs 104, 106, 108 to inform the PRUs 104, 106, 108 at which rate to sample or measure their V_{RECT} voltage levels and report the same to the PTU 102.

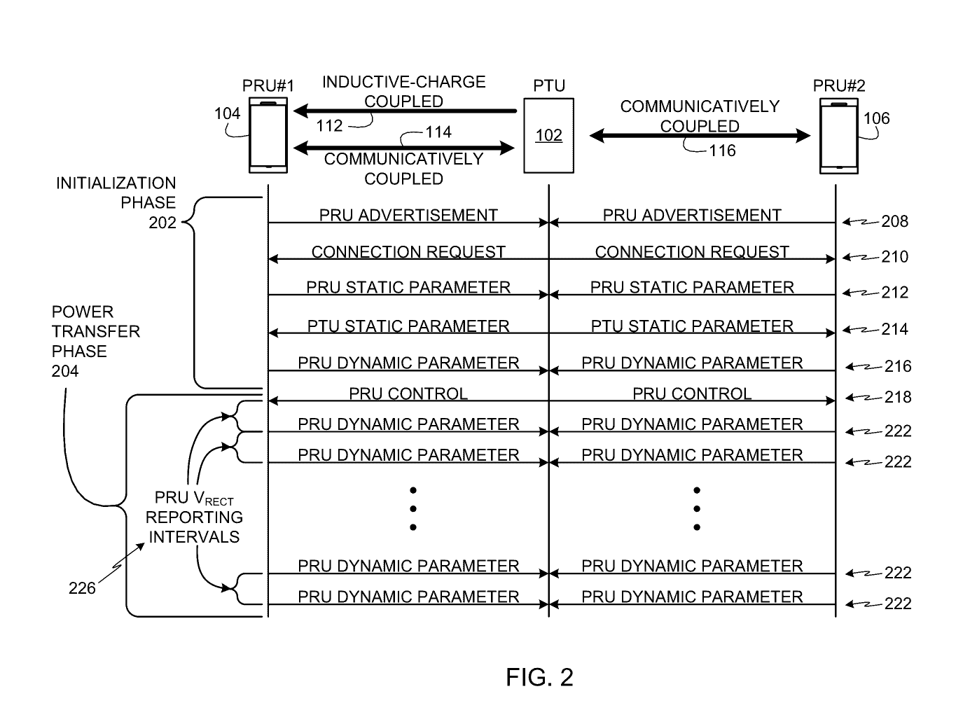

In some examples, the PRUs 104, 106, 108 over-sample their corresponding V_{RECT} voltage levels to generate more V_{RECT} voltage level measurements than the number of intervals at which the PTU 102 modulates its I_{COIL} electrical current at its Tx resonator. For example, if the PTU 102 sends a modulation interval duration value to the PRUs 104, 106, 108 of 4 ms, the PRUs 104, 106, 108 may over-sample their corresponding V_{RECT} voltage levels at 2 ms. Using such example over-sampling, for a 32-interval reference charging pattern modulated by the PTU 102, the PRUs 104, 106, 108 would measure and report 64 V_{RECT} voltage level measurements to the PTU 102. In some examples, such oversampling may be used to reduce or eliminate the effects of noise when reading the V_{RECT} voltage levels at Rx resonators of the PRUs 104, 106, 108 that could otherwise adversely affect the sampling accuracies of the V_{RECT} voltage level measurements. In some examples, such oversampling also facilitates synchronization between the PRUs 104, 106, 108 and the PTU 102. For example, the PRUs 104, 106, 108 are synchronized to the PTU 102 based on communications (e.g., PRU dynamic parameters 222 communicated at PRU V_{RECT} reporting intervals 226 as discussed below in connection with FIG. 2) received at the PTU 102 from the PRUs 104, 106, 108. As such, receiving communications at the PTU 102 more frequently from the PRUs 104, 106, 108 creates more opportunities based on the received communications to synchronize the PRUs 104, 106, 108 with the PTU 102 faster and with better accuracy.

In some examples, the PTU 102 and the PRUs 104, 106, 108 employ differential quantization to confirm when cross-connections exist. Differential quantization involves an encoding process at the PTU 102 and a quantization process at the PRUs 104, 106, 108. For example, in the encoding process, the PTU 102 performs differential encoding by using differential amplitude modulation to modulate the I_{COIL} electrical current at its Tx resonator based on the reference charging pattern 120. Such differential encoding decreases or eliminates phase ambiguity issues that could arise when a target PRU measures V_{RECT} voltage levels at a corresponding Rx resonator. For example, by using differential amplitude modulation, larger peak-to-peak amplitudes for the modulated I_{COIL} electrical current facilitate easier detectability and measurability of generated V_{RECT} voltage levels at Rx resonators of target PRUs. In the quantization process, the PRUs 104, 106, 108 are able to measure V_{RECT} voltage levels and generate V_{RECT} voltage level measurements using fewer bits (e.g., one to eight bits instead of 16 to 32 bits) to represent each V_{RECT} voltage level measurement. That is, using larger peak-to-peak amplitudes for the modulated I_{COIL} electrical current generated by the PTU 102 enables using a lower sampling resolution (e.g., fewer bits) to measure the V_{RECT} voltage levels with sufficient accuracy. Reducing the number of bits that the PRUs 104, 106, 108 need to send to the PTU 102 for each V_{RECT} voltage level measurement reduces bandwidth requirements, reduces processing resources required by the PRUs 104, 106, 108 to communicate the V_{RECT} voltage level measurements, and reduces processing resources required by the PTU 102 to receive such V_{RECT} voltage level measurements.

FIG. 2 is an example communication diagram of the OOB wireless communications 114, 116 between the PTU 102 and the PRUs 104, 106, 108 of FIG. 1 to detect cross-connection during a wireless charging process and to reduce or eliminate the effects of such cross-connection on wireless charging of the target PRU 104. In the illustrated example of FIG. 2, the target PRU 104 is shown as being inductive-charge coupled to the PTU 102 via the electromagnetic field 112 and communicatively coupled to the PTU 102 via the OOB wireless communications 114. In addition, the example non-target PRU 106 is shown as only being communicatively coupled to the PTU 102 via the OOB wireless communications 116. The OOB wireless communications 114 and 116 of the illustrated example are exchanged during an initialization phase 202 and a power transfer phase 204. During the initialization phase 202, the PTU 102 establishes communication with a PRU to initiate power transfer by the PTU 102 to wirelessly charge the PRU. For instances in which the PTU 102 establishes communication during the initialization phase 202 with a target PRU, such as the target PRU 104, that is in sufficiently close proximity to the PTU 102 to undergo wireless charging by the PTU 102 during the power transfer phase 204, there is no cross-connection between the target PRU and the PTU 102. However, for instances, in which the PTU 102 establishes communication during the initialization phase 202 with a non-target PRU, such as the non-target PRU 106, that is not within sufficiently close proximity to the PTU 102 to undergo wireless charging by the PTU 102 during the power transfer phase 204, there is cross-connection between the non-target PRU and the PTU 102. The OOB wireless communications 114, 116 between the PTU 102 and the PRUs 104, 106 of the illustrated example of FIG. 2 may be used by the PTU 102 in accordance with the teachings of this disclosure to detect such cross-connection. The example OOB wireless communications 114, 116 described below may be implemented in connection with an A4WP wireless charging standard. Additionally or alternatively, the example OOB wireless communications 114, 116 may be implemented in accordance with any other wireless charging standard. In addition, fewer or more OOB wireless communications than those shown in FIG. 2 may be used between the PTU 102 and the PRUs 104, 106 to implement examples disclosed herein.

During the initialization phase 202, the PTU 102 receives PRU advertisements 208 that are broadcast by the PRUs 104, 106. The PRU advertisements 208 of the illustrated example inform the PTU 102 that there is/are one or more PRUs 104, 106 within communication proximity (although not necessarily within wireless charging proximity) of the PTU 102. After the PTU 102 receives the PRU advertisements 208, the PTU 102 sends an example connection request 210. The example connection request 210 is used by the PTU 102 to inform the PRUs 104, 106 that the PTU 102 would like to associate (e.g., form an exclusive communication connection) with the PRUs 104, 106. In this manner, the PTU 102 can send and receive OOB wireless communications to and from the PRUs 104, 106 exclusive of other PRUs. In some examples, when the PRUs 104, 106 receive the connection request 210, the PRUs 104, 106 stop sending PRU advertisements 208.

In the illustrated example, the PRUs 104, 106 respond to the connection request 210 with corresponding example PRU static parameters 212. In the illustrated example, the PRU static parameters 212 describe characteristics and/or capabilities of the PRUs 104, 106. For example, the PRU static parameters 212 may describe a type of PRU device (e.g., wireless mobile telephone, camera, tablet, laptop, etc.), a PRU hardware version, a PRU firmware version, PRU communication capabilities, wireless charging standard protocol revision, PRU electrical characteristics (e.g., maximum rectifier power, maximum/minimum rectifier voltage, desired rectifier voltage, etc.), etc.

After the PTU 102 receives the PRU static parameters 212 from the PRUs 104, 106, the PTU 102 sends an example PTU static parameter 214 to the PRUs 104, 106. The example PTU static parameter 214 describes characteristics and/or capabilities of the PTU 102. For example, the PTU static parameter 214 may describe a maximum power deliverable by the PTU 102, a PTU hardware version, a PTU firmware version, PTU communication capabilities, wireless charging standard protocol revision, PTU electrical characteristics (e.g., PTU maximum source impedance, PTU maximum load resistance, etc.), maximum number of supported devices, etc.

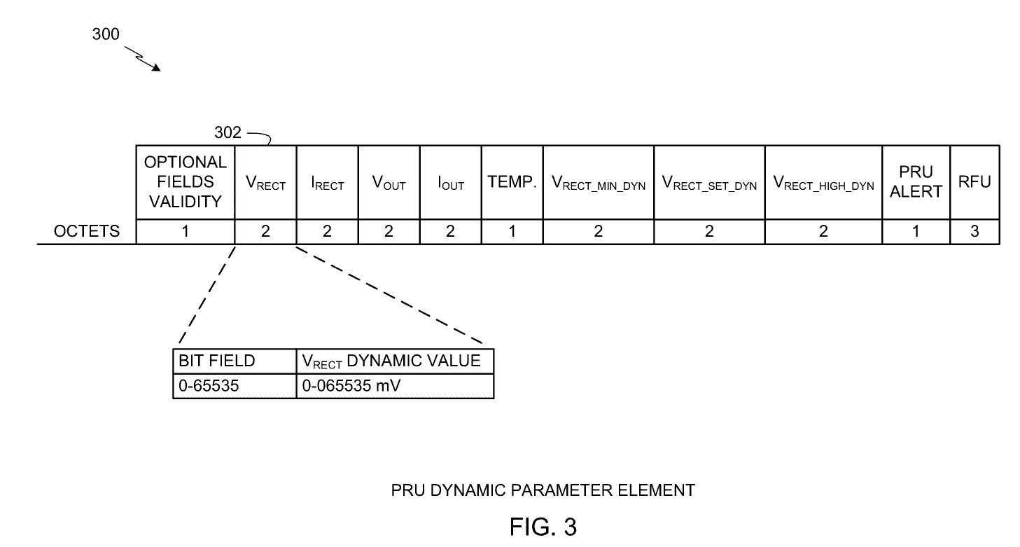

After the PRUs 104, 106 receive the PTU static parameter 214 from the PTU 102, the PRUs 104, 106 send corresponding example PRU dynamic parameters 216 to the PTU 102. In the illustrated example, the PRU dynamic parameters 216 provide measurements of the PRUs 104, 106 corresponding to parameters that change during a wireless charging process such as voltage values, current values, temperature values, etc. An example PRU dynamic parameter element 300 (e.g., a PRU dynamic parameter characteristic value) shown in FIG. 3 may be used to implement the PRU dynamic parameters 216.

In the illustrated example of FIG. 2, after the PTU 102 receives the PRU dynamic parameters 216, the initialization phase 202 ends and the power transfer phase 204 begins when the PTU 102 sends a PRU control message 218. In the illustrated example, the PTU 102 writes a value in the PRU control message 218 to start the power transfer phase 204 (e.g., to start wireless charging). During the power transfer phase 204, the PTU 102 modulates an electrical current (I_{COIL}) at its Tx resonator based on the example reference charging pattern 120 (FIG. 1) to vary the amount of power transferred via the electromagnetic field 112 (FIG. 1) at particular time intervals as described above in connection with FIG. 1. At the same particular time intervals, the PRUs 104, 106 sample or measure voltage levels (V_{RECT}) generated at their corresponding Rx resonators to generate corresponding measured charging patterns 122, 124 (FIG. 1) that are representative of high or low V_{RECT} voltage levels measured by the PRUs 104, 106 at those time intervals. In the illustrated example of FIG. 2, the PRUs 104, 106 send each measured V_{RECT} voltage level to the PTU 102 in corresponding PRU dynamic parameters 222 at PRU V_{RECT} reporting intervals 226.

In some examples, before the PTU 102 begins modulating the electrical current (I_{COIL}) at its Tx resonator, the PTU 102 informs the PRUs 104, 106 (e.g., through an OOB wireless communication 114, 116 such as the connection request 210, the PTU static parameter 214, or any other suitable communication separate from the connection request 210 and the PTU static parameter 214) of a time-to-modulation delay, a modulation interval duration, and a modulation interval quantity. In examples disclosed herein, a time-to-modulation delay specifies a time (e.g., a delay relative to a particular event such as transmission of the PRU control message 218) at which the PTU 102 will begin modulating the electrical current (I_{COIL}) at its Tx resonator and, thus, the time at which the PRUs 104, 106 are to begin to sample or measure voltage levels (V_{RECT}) generated at their corresponding Rx resonators. In examples disclosed herein, a modulation interval duration specifies the duration for which the PTU 102 will perform each modulation of the electrical current (I_{COIL}) at its Tx resonator corresponding to the different modulation levels of the reference charging pattern 120. In examples disclosed herein, a modulation interval quantity specifies the number of times that the PTU 102 will modulate the electrical current (I_{COIL}) at its Tx resonator to emit a complete reference charging pattern 120. For example, if the reference charging pattern 120 has ten voltage level intervals as in the illustrated example of FIG. 1, the modulation interval quantity is ten. In the illustrated example, the PRUs 104, 106 use the modulation interval duration from the PTU 102 to determine the time intervals at which to sample or measure voltage levels (V_{RECT}) generated at their corresponding Rx resonators. In some examples, the PRUs 104, 106 also use the modulation interval duration from the PTU 102 to determine how long to sample or measure at each modulation interval. In some examples, the time-to-modulation delay, a modulation interval duration, and/or the modulation interval quantity are dynamically selectable during operation of the PTU 102 based on one or more suitable criteria. For example, such criteria may include a type of PRU that is in communication with the PTU 102, PRU electrical characteristics, PRU hardware versions, PRU firmware versions, proximity of a PRU to the PTU 102, etc. In other examples, the PTU 102 does not send a time-to-modulation delay, a modulation interval duration, and/or a modulation interval quantity to the PRUs 104, 106. In such examples, the time-to-modulation delay, the modulation interval duration, and/or the modulation interval quantity may be fixed in accordance with a wireless charging standard such that the PRUs 104, 106 are configured to start sampling or measuring voltage levels (V_{RECT}) generated at their corresponding Rx resonators at a fixed time delay relative to a time of receipt of the PRU control message 218 and to perform such sampling or measuring at fixed interval durations.

In the illustrated example, durations of the PRU V_{RECT} reporting intervals 226 are the same as the time intervals at which the PRUs 104, 106 sample or measure the V_{RECT} voltage levels. For example, if the PTU 102 uses the reference charging pattern 120 of FIG. 1 which has ten modulation intervals, the PRUs 104, 106 will use ten of the PRU V_{RECT} reporting intervals 226 to communicate a complete measured charging pattern 122, 124 (FIG. 1) of measured V_{RECT} voltage levels to the PTU 102. That is, the PRUs 104, 106 will use each of the PRU dynamic parameters 222 to communicate a corresponding measured V_{RECT} voltage level during each of the ten modulation intervals.

FIG. 3 is an example PRU dynamic parameter element 300 that the PRUs 104, 106, 108 of FIGS. 1 and 2 use to send V_{RECT} voltage level measurements to the PTU 102 of FIGS. 1 and 2. For example, the PRUs 104, 106 may use the PRU dynamic parameter element 300 to send the PRU dynamic parameters 222 to the PTU 102. In particular, the example PRUs 104, 106 may store their measured V_{RECT} voltage level values in an example V_{RECT} field 302 of the PRU dynamic parameter element 300. The V_{RECT} field 302 of the illustrated example is a two octet field (e.g., a 16-bit field) in which millivolt (mV) values in the range of 0-65535 mV can be communicated to represent a particular V_{RECT} voltage level measured by the PRU 104, 106 during a corresponding PRU V_{RECT} reporting interval 226. As such, the PRUs 104, 106 use the example PRU dynamic parameter element 300 to send one V_{RECT} voltage level measurement during a corresponding one of the PRU V_{RECT} reporting intervals 226.

In some examples, upon receipt of the measured charging patterns 122, 124, 126 at the PTU 102, the PTU 102 decimates or decreases the number of bits of the V_{RECT} voltage level binary values (e.g., communicated in the V_{RECT} field 302) to represent the V_{RECT} voltage levels using a smaller number of bits (e.g., one to eight bits). In this manner, the PTU 102 can represent a measured charging pattern 122, 124, 126 using less bits for each V_{RECT} voltage level measurement that forms the measured charging pattern 122, 124, 126.

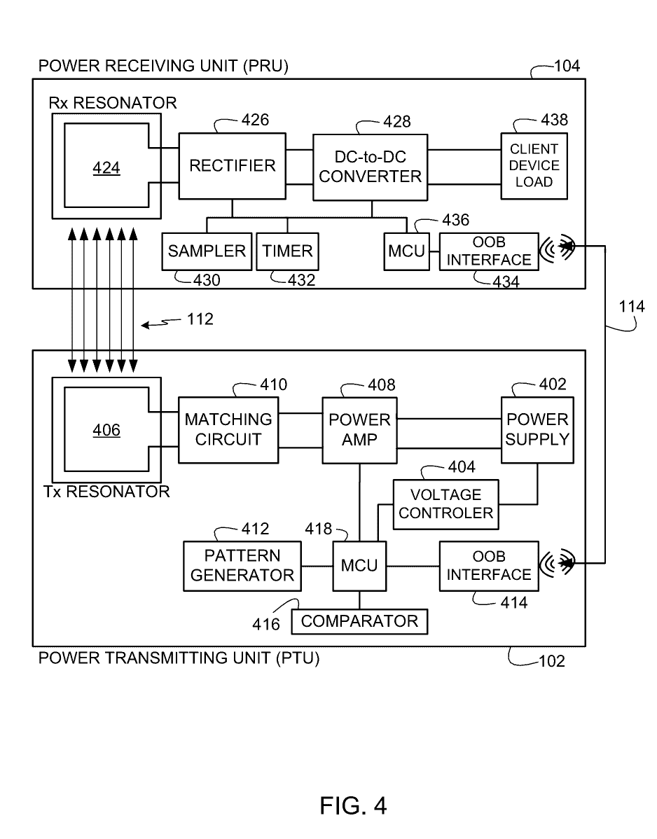

FIG. 4 depicts components of the example PTU 102 and the target PRU 104 of FIGS. 1 and 2. The PTU 102 and the target PRU 104 are shown in the illustrated example as being in wireless charging proximity and in wireless communication proximity to one another. In the illustrated example, the PTU 102 includes an example power supply 402, an example voltage controller 404, an example transmitter (Tx) resonator 406, an example power amplifier 408, an example matching circuit 410, an example pattern generator 412, a PTU out-of-band (OOB) communication interface 414, an example comparator 416, and an example microcontroller unit (MCU) 418 (e.g., a PTU MCU 418). Also in the illustrated example, the target PRU 104 includes an example receiver (Rx) resonator 424, an example rectifier 426, an example DC-to-DC converter 432, an example sampler 430, an example timer 432, an example PRU OOB communication interface 434, an example microcontroller unit (MCU) 436 (e.g., a PRU MCU 436), and an example client device load 438. The non-target PRUs 106, 108 of FIG. 1 may be structured using the same or similar configuration as the target PRU 104 shown in FIG. 4.

In the example PTU 102, the example power supply 402 regulates and supplies power to the PTU 102. For example, the power supply 402 may receive external power from an AC electrical source such as an electrical wall outlet. The example voltage controller 404 of the PTU 102 controls voltage levels and on/off states of the power supply 402. For example, the voltage controller 404 may control delivery of different voltage levels by the power supply 402 to different components or subsystems of the PTU 102 and may control voltage levels provided by the power supply 402 during low power modes or sleep modes of the PTU 102.

The example PTU 102 uses the Tx resonator 406 to generate (e.g., emit) the electromagnetic field 112 of FIG. 1 to wirelessly charge target PRUs. The Tx resonator 406 of the illustrated example is an inductive coil or antenna that generates the electromagnetic field 112 of FIG. 1 when electrical current is applied to the Tx resonator 406. The example PTU 102 uses the example power amplifier 408 to provide different levels of power to be applied to the Tx resonator 406 for transferring less or more power to the target PRU 104 via the electromagnetic field 112. For example, the amount of power provided by the power amplifier 408 is used to modulate the I_{COIL} electrical current applied at the TX resonator 406 based on high/low current levels indicated by the reference charging pattern 120 of FIG. 1. The example matching circuit 410 matches an input impedance of the Tx resonator 406 to an output impedance of the example power amplifier 408 to maximize power transfer (e.g., minimize signal reflection) between the power amplifier 408 and the Tx resonator 406.

In the illustrated example, the pattern generator 412 generates different reference charging patterns such as the example reference charging pattern 120 of FIG. 1. For example, the pattern generator 412 may generate a different reference charging pattern each time the PTU 102 connects or associates with one or more PRUs (e.g., based on the PRU advertisements 208 and the connection request 210 of FIG. 2). In some examples, the pattern generator 412 may use a random number generator or pseudo-random number generator to generate reference charging patterns using random patterns. In some examples, the pattern generator 412 may be omitted and the reference charging pattern used by the PTU 102 may be a fixed pattern that never changes or that is changed from time to time by an external source (e.g., changed through firmware updates). In some examples, different PTUs may have corresponding fixed reference charging patterns that are different from reference charging patterns of other PTUs.

The example PTU OOB communication interface 414 sends and receives OOB wireless communications 114 (FIGS. 1 and 2) to and from the target PRU 104. In the illustrated example, the PTU OOB communication interface 414 is implemented using a BLE wireless communication protocol. However, any other suitable communication protocol may be used such as an IEEE 802.11 wireless protocol, a ZigBee® wireless protocol, a near-field communication (NFC) wireless protocol, etc.

The example comparator 416 compares the measured charging pattern 122 (FIG. 1) received from the target PRU 104 (or the measured charging patterns 124, 126 received from non-target PRUs 106, 108 of FIGS. 1 and 2) to reference charging patterns (e.g., the reference charging pattern 120 of FIG. 1) generated by the pattern generator 412. The example PTU MCU 418 controls operations of the components of the PTU 102. For example, the PTU MCU 418 may be a processor or control that executes machine readable instructions to communicate with hardware and/or machine readable instructions of the components of the PTU 102 to control operations of those components in accordance with the teachings of this disclosure.

Turning now to the example target PRU 104, the Rx resonator 424 receives the electromagnetic field 112 (FIG. 1) generated by the Tx resonator 406 of the PTU 102. The Rx resonator 406 of the illustrated example is an inductive coil or antenna that senses the electromagnetic field 112 of FIG. 1 during a power transfer form the PTU 102 to generate an electrical current. The example rectifier 426 of the target PRU 104 provides V_{RECT} voltage levels associated with the Rx resonator 424 by converting electrical current that is generated by the Rx resonator 406 based on the power received via the electromagnetic field 112. The example DC-to-DC converter 428 conditions, decreases, and/or increases the V_{RECT} voltage from the rectifier 426. The example sampler 430 of the target PRU 104 samples or measures the V_{RECT} voltage values corresponding to the electromagnetic field 112 received at the Rx resonator 424. For example, the sampler 430 includes an analog-to-digital converter (ADC) that converts V_{RECT} voltage levels to binary values. In this manner, the binary V_{RECT} voltage levels can be communicated by the target PRU 104 as a V_{RECT} dynamic value in the 16-bit V_{RECT} field 302 of the PRU dynamic parameter element 300 of FIG. 3.

The example timer 432 of the target PRU 104 controls when the sampler 430 begins to sample or measure the V_{RECT} voltage levels, the time intervals at which the sampler 430 samples or measures the V_{RECT} voltage levels, and the durations for which the sampler 430 samples or measures the V_{RECT} voltage levels during each time interval. For example, the timer 432 may use a time-to-modulation delay, a modulation interval duration, and/or a modulation interval quantity that are provided by the PTU 102 or that are fixed in accordance with a wireless charging standard as described above in connection with FIG. 2.

The example PRU OOB communication interface 434 sends and receives OOB wireless communications 114 (FIGS. 1 and 2) to and from the PTU 102. In the illustrated example, the PRU OOB communication interface 434 is implemented using a BLE wireless communication protocol. However, any other suitable communication protocol may be used such as an IEEE 802.11 wireless protocol, a ZigBee® wireless protocol, a near-field communication (NFC) wireless protocol, etc.

The example PRU MCU 436 controls operations of the components of the target PRU 104. For example, the PRU MCU 436 may be a processor or controller that executes machine readable instructions to communicate with hardware and/or machine readable instructions of the components of the target PRU 104 to control operations of those components in accordance with the teachings of this disclosure. In the illustrated example, using the timer 432 to control the sampling by the sampler 430 enables offloading such sample collection management tasks from the PRU MCU 436. In this manner the PRU MCU 436 can use its processing resources to control the PRU OOB communication interface 434 to send and receive the OOB wireless communications 114 within communication protocol timings. For example, under circumstances in which a modulation interval duration selected by the PTU 102 for modulating the I_{COIL} electrical current at the Tx resonator 406 is very short (e.g., very fast), the PRU MCU 436 may not have sufficient resources to manage OOB wireless communications to report the measured V_{RECT} voltage levels (e.g., using the PRU dynamic parameters 222 of FIG. 2) to the PTU 102 and to also manage sampling of the V_{RECT} voltage levels. Under such circumstances, providing the timer 432 and the sampler 430 separate from the PRU MCU 436 enables offloading the V_{RECT} sampling management from the PRU MCU 436 to the timer 432 and the sampler 430.

The example client device load 438 is representative of other hardware of the target PRU 104 used to carry out functions of the target PRU 104. For example, if the target PRU 104 is a wireless mobile phone, the client device load 438 includes one or more processors, one or more radios, one or more memories, one or more displays, one or more cameras, etc. to implement the wireless mobile phone.

In the illustrated example of FIG. 2, the PTU MCU 418 of the PTU 102 controls the power amplifier 408 to modulate the electrical current (I_{COIL}) at the Tx resonator 406 based on a reference charging pattern (e.g., the reference charging pattern 120 of FIG. 1) to modulate power transferred via the electromagnetic field 112 from the Tx resonator 406 of the PTU 102 to the Rx resonator 424 of the target PRU 104. The target PRU 104 of the illustrated example uses the sampler 430 to sample or measure V_{RECT} voltage levels provided by the rectifier 426 based on the modulated electromagnetic field 112 sensed by the Rx resonator 424. The example sampler 430 samples or measures the V_{RECT} voltage levels over time (e.g., at the example PRU V_{RECT} reporting intervals 226 of FIG. 2) in accordance with a time-to-modulation delay, a modulation interval duration, and/or and a modulation interval quantity controlled by the timer 432 and/or the PRU MCU 436. The example PRU MCU 436 logs a binary number representing the V_{RECT} voltage level measurement sampled during a corresponding V_{RECT} measurement. The PRU OOB communication interface 434 communicates each binary-based V_{RECT} voltage level measurement to the PTU OOB communication interface 414 of the PTU 102 using a corresponding PRU dynamic parameter 222 of FIG. 2. For example, for each PRU V_{RECT} reporting interval 226 of FIG. 2, the PTU OOB communication interface 414 can use the example V_{RECT} field 302 of the PRU dynamic parameter element 300 of FIG. 3 to send a binary value representing the V_{RECT} voltage level measurement in a PRU dynamic parameter 222 to the PTU 102. In this manner, after completing a number of the PRU V_{RECT} reporting intervals 226, the target PRU 104 finishes the transmission of a complete measured charging pattern 122 to the PTU 102.

The example comparator 416 of the PTU 102 compares the measured charging pattern 122 provided by the target PRU 104 with the reference charging pattern 120 generated by the pattern generator 412 and used by the PTU MCU 418 to modulate the I_{COIL} electrical current applied to the Tx resonator 406. If the target PRU 104 is within wireless charging proximity of the PTU 102, the measured charging pattern 122 provided by the target PRU 104 to the PTU 102 will match or sufficiently match the reference charging pattern 120 generated by the pattern generator 412 of the PTU 102.

In the illustrated example, the comparator 416 uses a threshold (e.g., a bit-match threshold, a threshold number of matching bits, etc.) to determine whether the measured charging pattern 122 provided by the target PRU 104 sufficiently matches the reference charging pattern 120 generated by the pattern generator 412 of the PTU 102 to confirm that cross-connection does not exist between the PTU 102 and the target PRU 104. For example, the threshold may be selected at a design time of the PTU 102 or may be updated from time to time via, for example, firmware updates of the PTU 102 to specify a threshold number of bits or threshold percentage of bits of a measured charging pattern that must match corresponding bits of a reference charging pattern to confirm a match (e.g., to confirm that cross-connection does not exist for a particular PRU). In some examples, the comparator 416 uses an exact match rule to determine whether the measured charging pattern 122 provided by the target PRU 104 matches the reference charging pattern 120 generated by the pattern generator 412 of the PTU 102 to confirm that cross-connection does not exist between the PTU 102 and the target PRU 104. For example, when the comparator 416 uses an exact match rule, each bit of the measured charging pattern 122 must match a corresponding bit of the reference charging pattern 120 to confirm that a cross-connection does not exist between the PTU 102 and the target PRU 104. Thus, the example comparator 416 may be used to confirm a match between the measured charging pattern 122 and the reference charging pattern 120 based on a result of a comparison between the measured charging pattern 122 and the reference charging pattern 120 satisfying a threshold, when a threshold is used. Additionally or alternatively, the example comparator 416 may be used to confirm a match between the measured charging pattern 122 and the reference charging pattern 120 based on a result of a comparison between the measured charging pattern 122 and the reference charging pattern 120 indicating an exact match, when an exact match rule is used.

If a correlation between the measured charging pattern provided by a PRU and the reference charging pattern 120 generated by the pattern generator 412 of the PTU 102 is low (e.g., the correlation result is below a threshold, or the correlation result indicates the absence of an exact match when an exact match rule is used), the comparator 416 confirms a non-match to indicate a cross-connection between the PTU 102 and the PRU from which the PTU 102 received the measured charging pattern. Under such circumstances, the PTU MCU 418 removes the cross-connected PRU from a wireless charging eligibility device list of the PTU 102. For example, a wireless charging eligibility device list may be maintained by the PTU MCU 418 to identify PRUs that have not been identified as cross-connected with the PTU 102 and, thus, are eligible candidates as targets for receiving wireless charging by the PTU 102.

In some examples, the pattern generator 412 may use rows of a Hadamard matrix to generate reference charging patterns (e.g., the reference charging pattern 120 of FIG. 1). The rows of the Hadamard matrix are capable of performing sufficiently well as a reference charging pattern because they are orthogonal to each other. For example, if a reference charging pattern generated by the pattern generator 412 is selected from a 4-bit Hadamard matrix, the I_{COIL} electrical current variation applied by the PTU 102 to the Tx resonator 406 can take one of the four patterns: [+ + + + ], [− + − +], [− − + +], and [+ − − +], where “+” represents an increase in I_{COIL} electrical current (e.g., an I_{COIL}_{_}_{delta} of 5 milliamperes (mA)), and where “−” represents a decrease in I_{COIL} electrical current (e.g., an I_{COIL}_{_}_{delta} of 5 milliamperes (mA)). In some examples, performance of cross-connection detection can be improved by increasing the number of bits used for the reference charging pattern (e.g., increasing the size of the Hadamard matrix to an 8-bit matrix, a 16-bit matrix, a 32-bit matrix, etc.).

While example manners of implementing the PTU 102 and the target PRU1 104 of FIGS. 1 and 2 are illustrated in FIG. 4, one or more of the elements, processes and/or devices illustrated in FIG. 4 may be combined, divided, re-arranged, omitted, eliminated and/or implemented in any other way. Further, the example matching circuit 410, the example pattern generator 412, the PTU OOB communication interface 414, and/or the example comparator 416 of the PTU 102, and/or the example sampler 430, the example timer 432, and/or the example PRU OOB communication interface 434 of the target PRU 104 may be implemented by hardware, software, firmware and/or any combination of hardware, software and/or firmware. Thus, for example, any of the example matching circuit 410, the example pattern generator 412, the PTU OOB communication interface 414, and/or the example comparator 416 of the PTU 102, and/or the example sampler 430, the example timer 432, and/or the example PRU OOB communication interface 434 of the target PRU 104 could be implemented by one or more analog or digital circuit(s), logic circuits, programmable processor(s), application specific integrated circuit(s) (ASIC(s)), programmable logic device(s) (PLD(s)) and/or field programmable logic device(s) (FPLD(s)). When reading any of the apparatus or system claims of this patent to cover a purely software and/or firmware implementation, at least one of the example matching circuit 410, the example pattern generator 412, the PTU OOB communication interface 414, and/or the example comparator 416 of the PTU 102, and/or the example sampler 430, the example timer 432, and/or the example PRU OOB communication interface 434 of the target PRU 104 is/are hereby expressly defined to include a tangible computer readable storage device or storage disk such as a memory, a digital versatile disk (DVD), a compact disk (CD), a Blu-ray disk, etc. storing the software and/or firmware. Further still, the example PTU 102 and the example target PRU 104 may include one or more elements, processes and/or devices in addition to, or instead of, those illustrated in FIG. 4, and/or may include more than one of any or all of the illustrated elements, processes and devices.

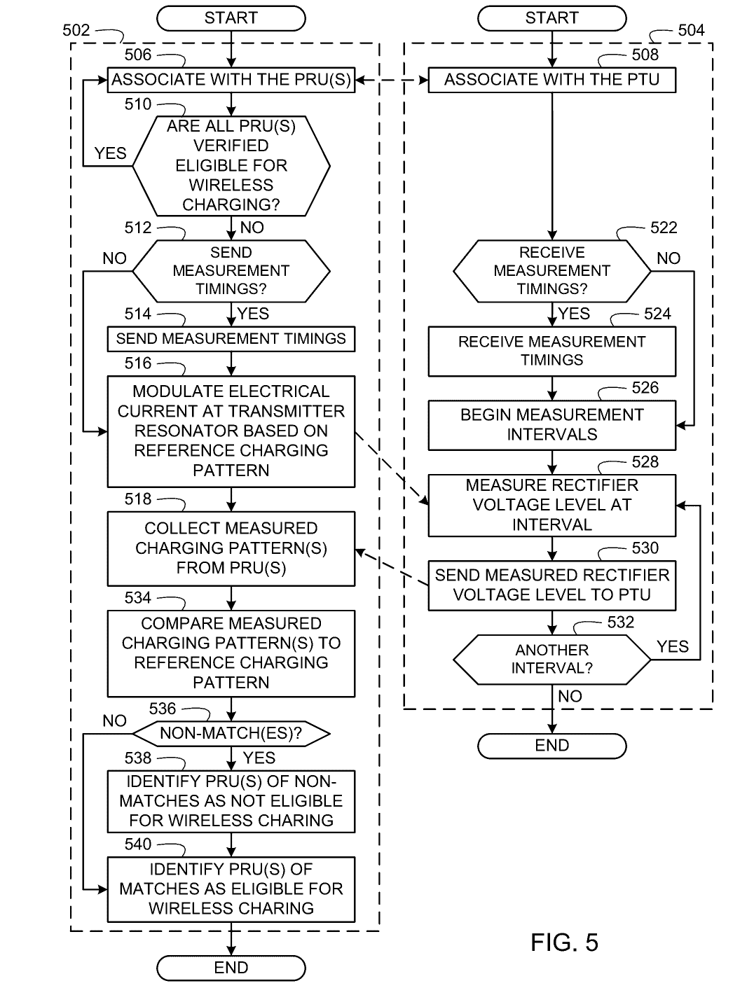

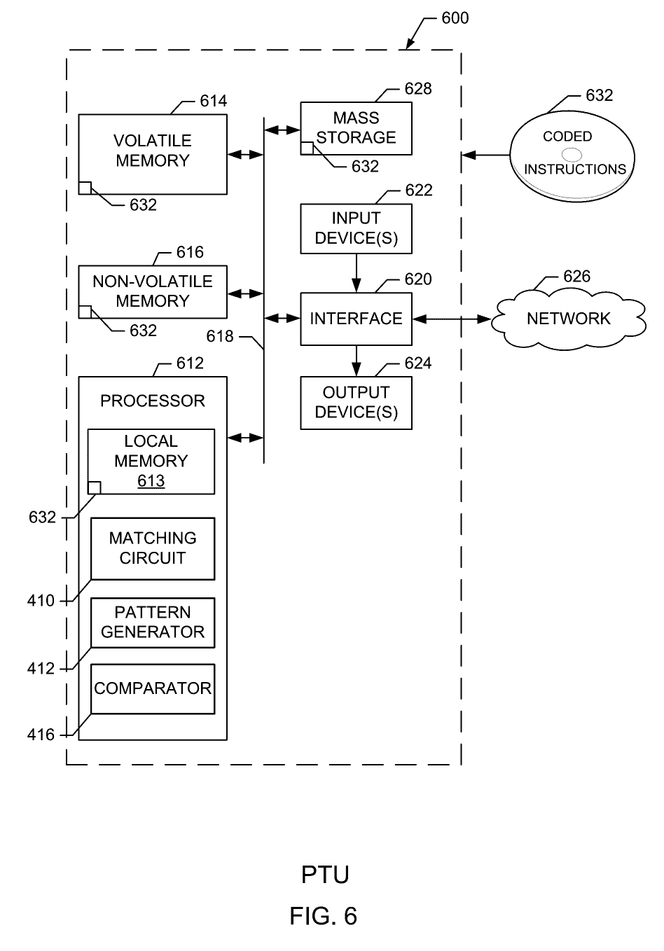

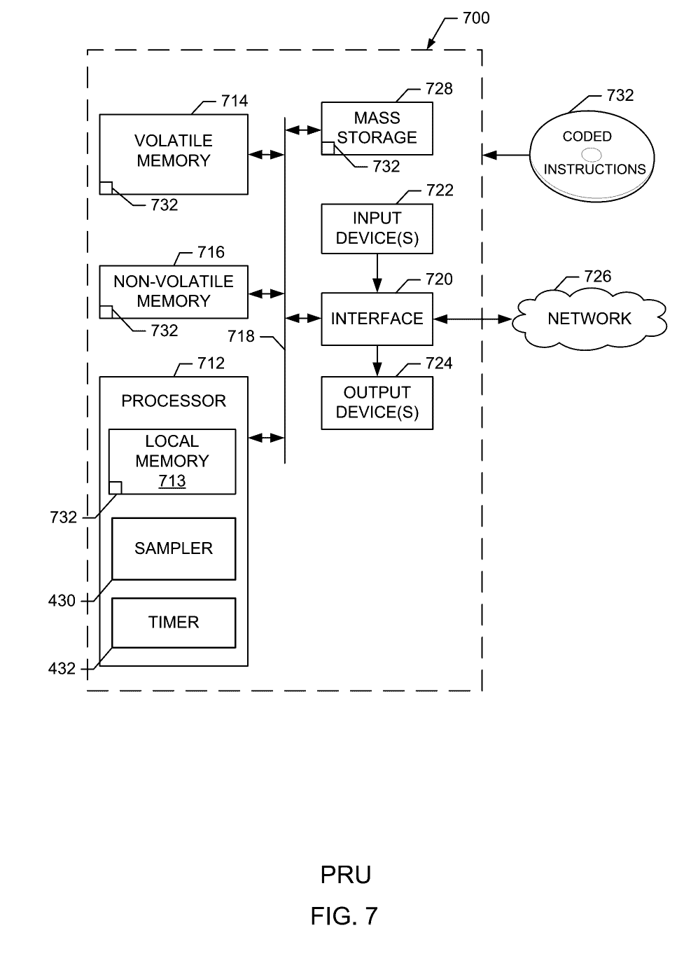

FIG. 5. depicts example flow diagrams representative of computer readable instructions that may be executed to implement the PTU 102 and the target PRU 104 of FIGS. 1, 2, and 4 to detect cross-connection associated with wireless charging to reduce or eliminate the effects of such cross-connection on wireless charging of the target PRU 104. The machine readable instructions represented by the example flow diagram of FIG. 5 include programs for execution by processors such as the processor 612 shown in the example processor platform 600 discussed below in connection with FIG. 6 and/or the processor 712 shown in the example processor platform 700 discussed below in connection with FIG. 7. The programs may be embodied in software stored on a tangible computer readable storage medium such as a CD-ROM, a floppy disk, a hard drive, a digital versatile disk (DVD), a Blu-ray disk, or a memory associated with the processor 612 and/or the processor 712, but the entire program and/or parts thereof could alternatively be executed by a device other than the processor 612 and/or the processor 712 and/or embodied in firmware or dedicated hardware. Further, although the example programs described with reference to the flow diagrams illustrated in FIG. 5, many other methods of implementing the example PTU 102 and the target PRU 104 may alternatively be used. For example, the order of execution of the blocks may be changed, and/or some of the blocks described may be changed, eliminated, or combined.

As mentioned above, the example processes of FIG. 5 may be implemented using coded instructions (e.g., computer and/or machine readable instructions) stored on a tangible computer readable storage medium such as a hard disk drive, a flash memory, a read-only memory (ROM), a compact disk (CD), a digital versatile disk (DVD), a cache, a random-access memory (RAM) and/or any other storage device or storage disk in which information is stored for any duration (e.g., for extended time periods, permanently, for brief instances, for temporarily buffering, and/or for caching of the information). As used herein, the term tangible computer readable storage medium is expressly defined to include any type of computer readable storage device and/or storage disk and to exclude propagating signals and to exclude transmission media. As used herein, “tangible computer readable storage medium” and “tangible machine readable storage medium” are used interchangeably. Additionally or alternatively, the example processes of FIG. 5 may be implemented using coded instructions (e.g., computer and/or machine readable instructions) stored on a non-transitory computer and/or machine readable medium such as a hard disk drive, a flash memory, a read-only memory, a compact disk, a digital versatile disk, a cache, a random-access memory and/or any other storage device or storage disk in which information is stored for any duration (e.g., for extended time periods, permanently, for brief instances, for temporarily buffering, and/or for caching of the information). As used herein, the term non-transitory computer readable medium is expressly defined to include any type of computer readable storage device and/or storage disk and to exclude propagating signals and to exclude transmission media. As used herein, when the phrase “at least” is used as the transition term in a preamble of a claim, it is open-ended in the same manner as the term “comprising” is open ended.

Turning now in detail to FIG. 5, the example programs of FIG. 5 are used to implement the PTU 102 and the target PRU 104. FIG. 5 shows an example PTU program to be executed by the PTU 102 in a PTU process 502, and an example PRU program to be executed by the target PRU 104 in a PRU process 504. The example PTU process 502 and the example PRU process 504 are shown and described together to facilitate an understanding of the interactions between the PTU 102 and the target PRU 104 during detection of cross-connection in association with a wireless charging process.

The example PTU process 502 begins when the PTU 102 associates with one or more PRU(s) (block 906). For example, the PTU 102 may use communications during the initialization phase 202 described above in connection with FIG. 2 to associate with one or more of the PRUs 104, 106, 108 (FIGS. 1 and 2). The example PRU process 504 begins when the target PRU 104 associates with the PTU 102 (block 908). For example, the PRU 104 may use communications during the initialization phase 202 described above in connection with FIG. 2 to associate with the PTU 102.

In the PTU process 502, the PTU MCU 418 (FIG. 4) determines whether all associated PRU(s) verified as eligible for wireless charging (block 510). For example, the PTU MCU 418 may maintain a wireless charging eligibility list that identifies PRUs that have been verified as being eligible for receiving wireless charging from the PTU 102. The PTU MCU 418 may compare device identifiers (e.g., PRU identifiers, media access control (MAC) addresses, etc.) of the PRU(s) that associated with the PTU 102 at block 506 with device identifiers in the wireless charging eligibility list to determine whether all of the associated PRU(s) are eligible for wireless charging.

If the PTU MCU 418 determines at block 510 that all of the associated PRU(s) are verified for wireless charging, control returns to block 506 at which the PTU 102 awaits to associate with other PRU(s). However, if the PTU MCU 418 determines at block 510 that not all of the associated PRU(s) are verified for wireless charging, control advances to block 512 at which the PTU MCU 418 determines whether to send measurement timings to the PRU(s) (block 512). For example, measurement timings may include the time-to-modulation delay, the modulation interval duration, and/or the modulation interval quantity described above. In some examples, the PTU 102 does not provide such measurement timings because measurement timings are stored at the PRU(s) in accordance with, for example, a wireless charging standard. If the PTU MCU 418 determines at block 512 that it should send measurement timings, the PTU OOB communications interface 414 of the PTU 102 sends the measurement timings to the PRU(s) (block 514). After sending the measurement timings at block 514, or if the PTU MCU 418 determines at block 512 not to send the measurement timings, control advances to block 516. Although blocks 512 and 514 associated with sending the measurement timings to the PRU(s) are shown as separate from the association operation of block 506, in other examples, the PTU 102 may send measurement timings to PRUs during the initialization phase 202 in which the PTU 102 associates with PRU(s) and exchanges characteristics and/or capabilities information with the PRU(s).

In the illustrated example, the PTU MCU 418 modulates the I_{COIL} electrical current at the Tx resonator 406 (FIG. 4) of the PTU 102 based on a reference charging pattern (block 516). For example, the PTU MCU 418 may obtain the reference charging pattern 120 from the pattern generator 412 (FIG. 4) to control the power amplifier 408 to modulate the I_{COIL} electrical current applied at the Tx resonator 406. In other examples, the reference charging pattern 120 may not be generated by the pattern generator 412 and may instead be a fixed value stored in the PTU 102. In some examples, the PTU 102 uses differential amplitude modulation to modulate the I_{COIL} electrical current at its Tx resonator 406 as part of a differential quantization technique (described above in connection with FIG. 1) to create a larger amplitude (e.g., a larger peak-to-peak amplitude) for the modulated I_{COIL} electrical current that can be more easily detected and measured by the Rx resonator 424 at the target PRU 104.

The PTU OOB communication interface 414 (FIG. 4) of the PTU 102 collects one or more measured charging pattern(s) from one or more PRU(s) (block 518). For example, the PTU OOB communication interface 414 may receive one or more of the measured charging patterns 122, 124, 126 of FIG. 1 from corresponding ones of the PRUs 104, 106, 108. Although the operations of blocks 516 and 518 are shown as occurring in series, the operations of blocks 516 and 518 are performed as an iterative process in which numerous I_{COIL} electrical current modulations are performed at different current modulation intervals as the PTU OOB communication interface 414 receives numerous V_{RECT} voltage level measurements via PRU dynamic parameters (e.g., the PRU dynamic parameters 222 of FIG. 2) from one or more associated PRU(s).

In the illustrated example of FIG. 5, operations of blocks 522, 524, 526, 528, and 530 are performed by the target PRU 104 during the example PRU process 504 substantially concurrently with the operations of blocks 512, 514, 516, and 518 of the example PTU process 502. In this manner, the target PRU 104 uses the operations of blocks 522, 524, 526, 528, and 530 to generate a measured charging pattern 122 (FIG. 1) and to send the measured charging pattern 122 to the PTU 102.

In the example PRU process 504, if the PRU MCU 436 determines that the target PRU 104 is to receive measurement timings (e.g., a time-to-modulation delay, a modulation interval duration, and/or a modulation interval quantity) from the PTU 102 (block 522), the PRU OOB communication interface 434 receives the measurement timings (block 524). In some examples, the target PRU 104 is not to receive measurement timings from the PTU 102. Instead in such examples, measurement timings are stored at the PRU(s) in accordance with, for example, a wireless charging standard.

After the PRU OOB communication interface 434 receives the measurement timings at block 524, or if the target PRU 104 is not to receive measurement timings from the PTU 102, the example sampler 430 (FIG. 4) of the target PRU 104 begins measurement intervals to measure the V_{RECT} voltage levels associated with the Rx resonator 424 (FIG. 4) of the PRU 104 (block 526). For example, the timer 432 (FIG. 4) uses a time-to-modulation delay to control when the sampler 430 is to begin measuring V_{RECT} voltage levels associated with the Rx resonator 424. At a measurement interval, the example sampler 430 measures the V_{RECT} voltage level (block 528). For example, the timer 432 uses a modulation interval duration to control times at which the sampler 430 measures V_{RECT} voltage levels associated with the Rx resonator 424. In the illustrated example, the modulation interval duration used by the timer 432 to control sampling of the V_{RECT} voltage levels is the same as durations of the PRU V_{RECT} reporting intervals 226 of FIG. 2. In some examples, the timer 432 uses an oversampling scheme as described above in connection with FIG. 1 to increase how often the sampler 430 measures the V_{RECT} voltage level so that the target PRU 104 generates and sends V_{RECT} voltage level measurements more frequently to the PTU 102. In some examples in which the PTU 102 uses differential amplitude modulation to modulate the I_{COIL} electrical current at its Tx resonator 406 as part of a differential quantization technique (described above in connection with FIG. 1), the sampler 430 of the target PRU 104 measures V_{RECT} voltage levels and generates V_{RECT} voltage level measurements using fewer bits (e.g., one to eight bits instead of 16 to 32 bits) to represent each V_{RECT} voltage level measurement.

The PRU OOB communication interface 434 (FIG. 4) sends the measured V_{RECT} voltage level to the PTU 102 (block 530). For example, the PRU OOB communication interface 434 sends the measured V_{RECT} voltage level value in the example V_{RECT} field 302 of the PRU dynamic parameter element 300 of FIG. 3 using one of the PRU dynamic parameters 222 of FIG. 2 during a PRU V_{RECT} reporting interval 226 of FIG. 2. The PRU MCU 436 and/or the timer 432 determine(s) whether there are more V_{RECT} measurement intervals (block 532). For example, the PRU MCU 436 and/or the timer 432 may determine whether there are more measurement intervals based on a modulation interval quantity that specifies how many times the PTU 102 modulates the I_{COIL} electrical current at the Tx resonator 406 to emit the reference charging pattern 120. Alternatively, in some examples, the PRU MCU 436 and/or the timer 432 continue to control the sampler 430 to perform V_{RECT} voltage level measurements at intervals until the PRU 104 becomes disassociated from the PTU 102. If the PRU MCU 436 and/or the timer 432 determine(s) at block 532 that there is another measurement interval, control returns to block 528. Otherwise, the target PRU 104 has finished sending a complete measured charging pattern 122 to the PTU 102, and the example PRU process 504 ends.

Returning to the example PTU process 502, after the PTU OOB communication interface 414 collects one or more measured charging pattern(s) 122, 124, 126 from the one or more associated PRU(s) 104, 106, 108 at block 518, the example comparator 416 (FIG. 4) compares the measured charging pattern(s) 122, 124, 126 to the reference charging pattern 120 (block 534). The example PTU MCU 418 and/or the example comparator 416 determine whether there are any non-matches between any measured charging pattern(s) 122, 124, 126 and the reference charging pattern 120 (block 536). For example, the comparator 416 performs the comparison of block 534 using a threshold that specifies a number or percentage of bits that must match between a measured charging pattern and a reference charging pattern to confirm a match. If the comparison of block 534 satisfies the threshold, the comparator 416 provides a confirmation to the PTU MCU 418 that a match is found between a measured charging pattern and a reference charging pattern. If a comparison of a measured charging pattern and a reference charging pattern does not satisfy the threshold, the comparator 416 notifies the PTU MCU 418 of a non-match. Alternatively, the comparator 416 may confirm a match or non-match based on whether the comparison result of block 534 is indicative of an exact match, when an exact match rule is used by the comparator 416.

If the PTU MCU 418 and/or the comparator 416 determines at block 536 that there is at least one non-match between a measured charging pattern(s) 122, 124, 126 and the reference charging pattern 120, the PTU MCU 418 identifies the corresponding cross-connected PRU(s) of the non-match(es) as not eligible for wireless charging by the PTU 102 (block 538). In the illustrated example of FIG. 1, the non-target PRUs 106, 108 correspond to measured charging patterns 124, 126 that are non-matches with the reference charging pattern 120. In the example of block 538 of FIG. 5, the PTU MCU 418 may remove the cross-connected non-target PRU(s) 106, 108 from a wireless charging eligibility device list of the PTU 102 and/or may label the cross-connected non-target PRU(s) 106, 108 in the wireless charging eligibility device list as not eligible for wireless charging by the PTU 102. In some examples, when the PTU 102 identifies a cross-connected non-target PRU, the PTU 102 disassociates from the cross-connected non-target PRU. In this manner, the cross-connected non-target PRU and the PTU 102 do not exchange further messages (e.g., charging status messages) regarding a wireless charging process. As such, the cross-connected non-target PRUs do not needlessly consume their battery power and/or processing resources by sending further messages related to wireless charging to the PTU 102. In some examples, the PTU 102 keeps the wireless charging non-eligible status of a cross-connected non-target PRU for a particular amount of time (e.g., minutes, hours, days, etc.). In such examples, the PTU 102 removes the wireless charging non-eligible status from PRUs that were previously identified as cross-connected non-target PRUs at block 538. In this manner, the PTU 102 may at some later time again determine whether those same PRUs become eligible for wireless charging (e.g., due to one or more users placing the PRUs within wireless charging proximity of the PTU 102).

After identifying the corresponding cross-connected PRU(s) of the non-match(es) as not eligible for wireless charging by the PTU 102 at block 538, or if the PTU MCU 418 and/or the comparator 416 determine(s) at block 536 that there are no non-matches between the measured charging patterns 122, 124, 126 and the reference charging pattern 120, the PTU MCU identifies PRU(s) corresponding to measured charging patterns that match the reference charging pattern 120 as eligible for wireless charging by the PTU 102 (block 540). In the illustrated example of FIG. 1, the target PRU 104 corresponds to a measured charging pattern 122 that matches the reference charging pattern 120. In example block 540 of FIG. 5, the PTU MCU 418 keeps the target PRU 104 in a wireless charging eligibility device list of the PTU 102 to indicate the eligibility of the target PRU 104 for wireless charging by the PTU 102 and/or may label the target PRU 104 in the wireless charging eligibility device list as eligible for wireless charging by the PTU 102. The example PTU process 502 of FIG. 5 then ends.

Although the example PTU process 502 and the example PRU process 504 are shown as ending in the illustrated example, the processes 502 and 504 may be repeated any number of times. For example, the PTU process 502 may be repeated by the PTU 102 any time a PRU associates with the PTU 102. In addition, the PRU process 504 may be repeated by the PRU 104 any time the PRU 104 associates with a PTU. Also, although the PTU process 502 is shown in association with a single PRU process 504, the PTU process 502 may be performed in parallel with numerous PRU processes that are performed by any number of PRUs that are associated with the PTU 102.

FIG. 6 is an example processor platform 600 capable of executing the computer readable instructions represented in the PTU phase 502 of the example flow diagram of FIG. 5 to implement the example PTU 102 of FIGS. 1, 2, and 4 to detect cross-connection and substantially reduce or eliminate the effects of such cross-connection on wireless charging of the target PRU 104 of FIGS. 1, 2, and 4. The processor platform 600 of the illustrated example includes a processor 612. The processor 612 of the illustrated example is hardware. For example, the processor 612 can be implemented by one or more integrated circuits, logic circuits, microprocessors or controllers from any desired family or manufacturer. In the illustrated example, the processor 612 implements the PTU MCU 418 of FIG. 4. Also in the illustrated example, the processor 612 includes the example matching circuit 410, the example pattern generator 412, and the example comparator 416 of FIG. 4.

The processor 612 of the illustrated example includes a local memory 613 (e.g., a cache). The processor 612 of the illustrated example is in communication with a main memory including a volatile memory 614 and a non-volatile memory 616 via a bus 618. The volatile memory 614 may be implemented by Synchronous Dynamic Random Access Memory (SDRAM), Dynamic Random Access Memory (DRAM), RAMBUS Dynamic Random Access Memory (RDRAM) and/or any other type of random access memory device. The non-volatile memory 616 may be implemented by flash memory and/or any other desired type of memory device. Access to the main memory 614, 616 is controlled by a memory controller.

The processor platform 600 of the illustrated example also includes an interface circuit 620. In the illustrated example, the interface circuit 620 is implemented by a wireless interface in circuit with one or more antennas. For example, the interface circuit 620 of the illustrated example performs wireless communication operations (e.g., modulation, demodulation, amplification, etc.) to transmit and/or receive information wirelessly. In the illustrated example, the interface circuit 620 is used to implement the PTU OOB communication interface 414 of FIG. 4. The interface circuit 620 of the illustrated example is implemented based on a Bluetooth® wireless protocol. Additionally or alternatively, the interface circuit 620 may be implemented using one or more other example wireless protocols such as an IEEE 802.11 wireless protocol, a ZigBee® wireless protocol, a near-field communication (NFC) wireless protocol, etc. Additionally or alternatively, the interface circuit 620 may be implemented by any other type of interface standard, such as an Ethernet interface, a universal serial bus (USB), and/or a PCI express interface.

In the illustrated example, one or more input devices 622 are connected to the interface circuit 620. The input device(s) 622 permit(s) a user to enter data and commands into the processor 612. The input device(s) can be implemented by, for example, an audio sensor, a microphone, a camera (still or video), a keyboard, a button, a mouse, a touchscreen, a track-pad, a trackball, isopoint and/or a voice recognition system.

One or more output devices 624 are also connected to the interface circuit 620 of the illustrated example. The output devices 624 can be implemented, for example, by display devices (e.g., a light emitting diode (LED), an organic light emitting diode (OLED), a liquid crystal display, a cathode ray tube display (CRT), a touchscreen, a tactile output device, a printer and/or speakers). The interface circuit 620 of the illustrated example, thus, typically includes a graphics driver card, a graphics driver chip or a graphics driver processor.

The interface circuit 620 of the illustrated example also includes a communication device such as a transmitter, a receiver, a transceiver, a modem and/or network interface card to facilitate exchange of data with external machines (e.g., computing devices of any kind) via a network 626 (e.g., an wired or wireless Ethernet connection, a digital subscriber line (DSL), a telephone line, coaxial cable, a cellular telephone system, a Bluetooth wireless connection, etc.).

The processor platform 600 of the illustrated example also includes one or more mass storage devices 628 for storing software and/or data. Examples of such mass storage devices 628 include floppy disk drives, hard drive disks, compact disk drives, Blu-ray disk drives, RAID systems, and digital versatile disk (DVD) drives.

Coded instructions 632 represented by the operations in the PTU phase 502 of the flow diagram of FIG. 5 may be stored in the mass storage device 628, in the volatile memory 614, in the non-volatile memory 616, and/or on a removable tangible computer readable storage medium such as a CD or DVD.

FIG. 7 is an example processor platform 700 capable of executing the computer readable instructions represented in the PRU phase 504 of the example flow diagram of FIG. 5 to implement the example target PRU 104 of FIGS. 1, 2, and 4 to detect cross-connection and substantially reduce or eliminate the effects of such cross-connection on wireless charging of the target PRU 104. The processor platform 700 of the illustrated example includes a processor 712. The processor 712 of the illustrated example is hardware. For example, the processor 712 can be implemented by one or more integrated circuits, logic circuits, microprocessors or controllers from any desired family or manufacturer. In the illustrated example, the processor 712 implements the PRU MCU 436 of FIG. 4. Also in the illustrated example, the processor 712 includes the example sampler 430 and the example timer 432 of FIG. 4.

The processor 712 of the illustrated example includes a local memory 713 (e.g., a cache). The processor 712 of the illustrated example is in communication with a main memory including a volatile memory 714 and a non-volatile memory 716 via a bus 718. The volatile memory 714 may be implemented by Synchronous Dynamic Random Access Memory (SDRAM), Dynamic Random Access Memory (DRAM), RAMBUS Dynamic Random Access Memory (RDRAM) and/or any other type of random access memory device. The non-volatile memory 716 may be implemented by flash memory and/or any other desired type of memory device. Access to the main memory 714, 716 is controlled by a memory controller.

The processor platform 700 of the illustrated example also includes an interface circuit 720. In the illustrated example, the interface circuit 720 is implemented by a wireless interface in circuit with one or more antennas. For example, the interface circuit 720 of the illustrated example performs wireless communication operations (e.g., modulation, demodulation, amplification, etc.) to transmit and/or receive information wirelessly. In the illustrated example, the interface circuit 720 is used to implement the PRU OOB communication interface 434 of FIG. 4. The interface circuit 720 of the illustrated example is implemented based on a Bluetooth® wireless protocol. Additionally or alternatively, the interface circuit 720 may be implemented using one or more other example wireless protocols such as an IEEE 802.11 wireless protocol, a ZigBee® wireless protocol, a near-field communication (NFC) wireless protocol, etc. Additionally or alternatively, the interface circuit 720 may be implemented by any other type of interface standard, such as an Ethernet interface, a universal serial bus (USB), and/or a PCI express interface.

In the illustrated example, one or more input devices 722 are connected to the interface circuit 720. The input device(s) 722 permit(s) a user to enter data and commands into the processor 712. The input device(s) can be implemented by, for example, an audio sensor, a microphone, a camera (still or video), a keyboard, a button, a mouse, a touchscreen, a track-pad, a trackball, isopoint and/or a voice recognition system.

One or more output devices 724 are also connected to the interface circuit 720 of the illustrated example. The output devices 724 can be implemented, for example, by display devices (e.g., a light emitting diode (LED), an organic light emitting diode (OLED), a liquid crystal display, a cathode ray tube display (CRT), a touchscreen, a tactile output device, a printer and/or speakers). The interface circuit 720 of the illustrated example, thus, typically includes a graphics driver card, a graphics driver chip or a graphics driver processor.

The interface circuit 720 of the illustrated example also includes a communication device such as a transmitter, a receiver, a transceiver, a modem and/or network interface card to facilitate exchange of data with external machines (e.g., computing devices of any kind) via a network 726 (e.g., an wired or wireless Ethernet connection, a digital subscriber line (DSL), a telephone line, coaxial cable, a cellular telephone system, a Bluetooth wireless connection, etc.).

The processor platform 700 of the illustrated example also includes one or more mass storage devices 728 for storing software and/or data. Examples of such mass storage devices 728 include floppy disk drives, hard drive disks, compact disk drives, Blu-ray disk drives, RAID systems, and digital versatile disk (DVD) drives.

Coded instructions 732 represented by the operations in the PRU phase 504 of the flow diagram of FIG. 5 may be stored in the mass storage device 728, in the volatile memory 714, in the non-volatile memory 716, and/or on a removable tangible computer readable storage medium such as a CD or DVD.

Examples disclosed herein are useful to detect instances of cross-connection between PRUs and PTUs, and substantially reduce or eliminate adverse effects of such cross-connection on wireless charging of target PRUs. An example adverse effect that can be substantially decreased or eliminated using examples disclosed herein includes instances of a PTU overcharging a target PRU when the PTU fails to receive a charge complete message from the target PRU because the PTU is communicatively cross-connected to a different, non-target PRU. Another example adverse effect that can be substantially decreased or eliminated using examples disclosed herein includes instances of the PTU receiving incorrect charging parameters from a cross-connected non-target PRU and using the incorrect charging parameters to charge a target PRU in a non-optimal manner that could undercharge the target PRU and/or damage the target PRU.

In addition, examples disclosed herein may be used to reduce wireless transmissions of non-target PRUs by removing cross-connected non-target PRUs from wireless charging eligibility device lists and/or labeling cross-connected non-target PRUs as not eligible for wireless charging in wireless charging eligibility device lists. For example, by removing cross-connected non-target PRUs from wireless charging eligibility device lists and/or labeling cross-connected non-target PRUs as not eligible for wireless charging, the cross-connected non-target PRUs can stop sending wireless communications (e.g., charging status updates) about wireless charging to a PTU, thereby conserving battery power and processing resources of the cross-connected non-target PRUs. Reducing wireless transmissions is useful to conserve battery power in battery-operated wireless devices. Power conservation is typically a significant design goal of engineers when designing wireless devices, software for wireless devices, and/or firmware for wireless devices. For example, every time a wireless transmission is made by a wireless device, a radio transmitter of the wireless device consumes a substantial amount of power to ensure that a sufficiently powerful radio frequency (RF) signal is emitted so that the wireless transmission is strong enough to be detected by a receiving device. As such, each emitted wireless transmission consumes battery power, which over time reduces the useful battery life of a wireless device. Thus, reducing wireless transmissions increases useful battery life of wireless devices. Reducing wireless transmissions using examples disclosed herein also conserves battery power of wireless devices by reducing the amount of processing that needs to be performed by the wireless devices. For example, when information is wirelessly communicated by a wireless device, the wireless device uses processing resources to generate frames, messages, and/or any other information delivery units used to send wireless transmissions. Such processing resources consume battery power, which over time reduces the useful battery life of a wireless device. As such, using examples disclosed herein enables reducing battery power consumption in battery-operated wireless devices at least by reducing wireless transmissions and reducing the use of processing resources, which in turn enables increasing battery life of wireless devices so that such wireless devices can operate longer between battery charges and/or battery replacements.

Reducing wireless transmissions between PTUs and PRUs using examples disclosed herein is also useful to reduce use of RF bandwidth and network resources. For example, when a wireless device emits a wireless transmission, RF bandwidth is used to transmit the wireless transmission and a receiving device uses processing resources to process the wireless transmission. Decreasing wireless transmissions allows RF bandwidth to remain available for other uses such as for transmissions by other wireless devices. In addition, network resources of network devices can be more readily available for other uses such as processing transmissions by other wireless devices. Accordingly, examples disclosed herein enable more efficient use of RF bandwidth and network resources which can in turn decrease network congestion and facilitate servicing more wireless clients at network access points.

The following pertain to further examples disclosed herein.

Example 1 is a method to detect eligibility for wireless charging at a power transmitting unit. The method of Example 1 includes receiving a measured charging pattern from a power receiving unit that is in communication with the power transmitting unit. The method of Example 1 also includes determining that the power receiving unit is not eligible for wireless charging by the power transmitting unit when the measured charging pattern does not match a reference charging pattern used to modulate an electrical current at a transmitter resonator of the power transmitting unit. The method of Example 1 also includes determining that the power receiving unit is eligible for wireless charging by the power transmitting unit when the measured charging pattern does match the reference charging pattern.

In Example 2, the subject matter of Example 1 can optionally include that the reference charging pattern represents a plurality of high electrical current levels and low electrical current levels.

In Example 3, the subject matter of any one of Examples 1-2 can optionally include that modulating the electrical current at the transmitter resonator of the power transmitting unit based on the reference charging pattern includes applying the high electrical current levels and the low electrical current levels at the transmitter resonator at corresponding intervals of the reference charging pattern.

In Example 4, the subject matter of any one of Examples 1-3 can optionally include determining whether the measured charging pattern matches the reference charging pattern by determining whether the measured charging pattern sufficiently matches the reference charging pattern within a threshold.

In Example 5, the subject matter of any one of Examples 1-4 can optionally include confirming a cross-connection between the power transmitting unit and the power receiving unit when the measured charging pattern does not match the reference charging pattern.

In Example 6, the subject matter of any one of Examples 1-5 can optionally include that the cross-connection is indicative of the power receiving unit being within wireless communication range of the power transmitting unit but not within wireless charging proximity of the power transmitting unit.

In Example 7, the subject matter of any one of Examples 1-6 can optionally include sending a time-to-modulation delay value and a modulation interval duration value from the power transmitting unit to the power receiving unit, the time-to-modulation delay value to inform the power receiving unit when to begin measuring a rectifier voltage level associated with a receiving resonator of the power receiving unit, and the modulation interval duration value to inform the power receiving unit of interval durations at which to perform measurements of the rectifier voltage level.

In Example 8, the subject matter of any one of Examples 1-7 can optionally include that receiving the measured charging pattern from the power receiving unit includes receiving a plurality of separate rectifier voltage measurement values from the power receiving unit at corresponding reporting intervals, the separately received rectifier voltage measurement values forming the measured charging pattern.

In Example 9, the subject matter of any one of Examples 1-8 can optionally include that the power receiving unit is a wireless mobile device.

In Example 10, the subject matter of any one of Examples 1-9 can optionally include that the power transmitting unit is a wireless charging station.

In Example 11, the subject matter of any one of Examples 1-10 can optionally include that the measured charging pattern is received from the power receiving unit using a direct, wireless peer-to-peer connection between the power transmitting unit and the power receiving unit.

Example 12 is a power transmitting unit to detect eligibility of a power receiving unit for wireless charging. The power transmitting unit of Example 12 includes a communication interface to receive a measured charging pattern from the power receiving unit that is in communication with the power transmitting unit. The power transmitting unit of Example 12 also includes a processor to determine that the power receiving unit is not eligible for wireless charging by the power transmitting unit when the measured charging pattern does not match a reference charging pattern used to modulate an electrical current at a transmitter resonator of the power transmitting unit. The processor of Example 12 is also to determine that the power receiving unit is eligible for wireless charging by the power transmitting unit when the measured charging pattern does match the reference charging pattern.

In Example 13, the subject matter of Example 12 can optionally include that the reference charging pattern represents a plurality of high electrical current levels and low electrical current levels.

In Example 14, the subject matter of any one of Examples 12-13 can optionally include a power amplifier to modulate the electrical current at the transmitter resonator of the power transmitting unit based on the reference charging pattern by applying the high electrical current levels and the low electrical current levels at the transmitter resonator at corresponding intervals of the reference charging pattern.

In Example 15, the subject matter of any one of Examples 12-14 can optionally include a comparator to determine whether the measured charging pattern matches the reference charging pattern based on a threshold number of bits of the measured charging pattern matching corresponding bits of the reference charging pattern.

In Example 16, the subject matter of any one of Examples 12-15 can optionally include that the processor is further to confirm a cross-connection between the power transmitting unit and the power receiving unit when the measured charging pattern does not match the reference charging pattern.

In Example 17, the subject matter of any one of Examples 12-16 can optionally include that the cross-connection is indicative of the power receiving unit being within wireless communication range of the power transmitting unit but not within wireless charging proximity of the power transmitting unit.

In Example 18, the subject matter of any one of Examples 12-17 can optionally include that the communication interface is further to send a time-to-modulation delay value and a modulation interval duration value to the power receiving unit, the time-to-modulation delay value to inform the power receiving unit when to begin measuring a rectifier voltage level associated with a receiving resonator of the power receiving unit, and the modulation interval duration value to inform the power receiving unit of interval durations at which to perform measurements of the rectifier voltage level.

In Example 19, the subject matter of any one of Examples 12-18 can optionally include that the communication interface is to receive the measured charging pattern from the power receiving unit by receiving a plurality of separate rectifier voltage measurement values from the power receiving unit at corresponding reporting intervals, the separately received rectifier voltage measurement values forming the measured charging pattern.

In Example 20, the subject matter of any one of Examples 12-19 can optionally include that the power receiving unit is a wireless mobile device.

In Example 21, the subject matter of any one of Examples 12-20 can optionally include that the power transmitting unit is a wireless charging station.

In Example 22, the subject matter of any one of Examples 12-21 can optionally include that the communication interface is to use a direct, wireless peer-to-peer connection between the power transmitting unit and the power receiving unit to receive the measured charging pattern from the power receiving unit.

Example 23 is an article of manufacture including computer readable instructions that, when executed, cause a machine to receive a measured charging pattern from a power receiving unit that is in communication with a power transmitting unit. The instructions of Example 23 also cause the machine to determine that the power receiving unit is not eligible for wireless charging by the power transmitting unit when the measured charging pattern does not match a reference charging pattern used to modulate an electrical current at a transmitter resonator of the power transmitting unit. The instructions of Example 23 also cause the machine to determine that the power receiving unit is eligible for wireless charging by the power transmitting unit when the measured charging pattern does match the reference charging pattern.

In Example 24, the subject matter of Example 23 can optionally include that the reference charging pattern represents a plurality of high electrical current levels and low electrical current levels.

In Example 25, the subject matter of any one of Examples 23-24 can optionally include that the instructions are to further cause the machine to modulate the electrical current at the transmitter resonator of the power transmitting unit based on the reference charging pattern by applying the high electrical current levels and the low electrical current levels at the transmitter resonator at corresponding intervals of the reference charging pattern.

In Example 26, the subject matter of any one of Examples 23-25 can optionally include that the instructions are to further cause the machine to determine whether the measured charging pattern matches the reference charging pattern by determining whether a threshold number of bits of the measured charging pattern match corresponding bits of the reference charging pattern.

In Example 27, the subject matter of any one of Examples 23-26 can optionally include that the instructions are to further cause the machine to confirm a cross-connection between the power transmitting unit and the power receiving unit when the measured charging pattern does not match the reference charging pattern.

In Example 28, the subject matter of any one of Examples 23-27 can optionally include that the cross-connection is indicative of the power receiving unit being within wireless communication range of the power transmitting unit but not within wireless charging proximity of the power transmitting unit.

In Example 29, the subject matter of any one of Examples 23-28 can optionally include that the instructions are to further cause the machine to send a time-to-modulation delay value and a modulation interval duration value from the power transmitting unit to the power receiving unit, the time-to-modulation delay value to inform the power receiving unit when to begin measuring a rectifier voltage level associated with a receiving resonator of the power receiving unit, and the modulation interval duration value to inform the power receiving unit of interval durations at which to perform measurements of the rectifier voltage level.

In Example 30, the subject matter of any one of Examples 23-29 can optionally include that the instructions are to cause the machine to receive the measured charging pattern from the power receiving unit includes receiving a plurality of separate rectifier voltage measurement values from the power receiving unit at corresponding reporting intervals, the separately received rectifier voltage measurement values forming the measured charging pattern.

In Example 31, the subject matter of any one of Examples 23-30 can optionally include that the power receiving unit is a wireless mobile device.

In Example 32, the subject matter of any one of Examples 23-31 can optionally include that the power transmitting unit is a wireless charging station.

In Example 33, the subject matter of any one of Examples 23-32 can optionally include that the instructions are to cause the machine to receive the measured charging pattern from the power receiving unit using a direct, wireless peer-to-peer connection between the power transmitting unit and the power receiving unit.

Example 34 is a method to measure a charging pattern at a power receiving unit. The method of Example 34 includes receiving a time-to-modulation delay value and a modulation interval duration value at the power receiving unit from a power transmitting unit, the time-to-modulation delay specifying when the power transmitting unit is to start modulating electrical current at a transmitter resonator, and the modulation interval duration specifying a duration for which the power transmitting unit is to hold an electrical current level at the transmitter resonator. The method of Example 34 also includes measuring rectifier voltage levels associated with a receiver resonator of the power receiving unit a plurality of times based on the time-to-modulation delay value and the modulation interval duration value to generate a measured charging pattern. The method of Example 34 also includes sending the measured charging pattern to the power transmitting unit.

In Example 35, the subject matter of Example 34 can optionally include that the sending of the measured charging pattern to the power transmitting unit includes sending separate ones of the measured rectifier voltage levels during separate rectifier voltage reporting intervals.

In Example 36, the subject matter of any one of Examples 34-35 can optionally include that the power receiving unit is a wireless mobile device.

In Example 37, the subject matter of any one of Examples 34-36 can optionally include that the power transmitting unit is a wireless charging station.

In Example 38, the subject matter of any one of Examples 34-37 can optionally include that a direct, wireless peer-to-peer connection between the power transmitting unit and the power receiving unit is used to receive the time-to-modulation delay value and the modulation interval duration at the power receiving unit, and to send the measured charging pattern to the power transmitting unit.

Example 39 is a power receiving unit to measure a charging pattern. The power receiving unit of Example 39 includes a communication interface to receive a time-to-modulation delay value and a modulation interval duration value at the power receiving unit from a power transmitting unit, the time-to-modulation delay specifying when the power transmitting unit is to start modulating electrical current at a transmitter resonator, and the modulation interval duration specifying a duration for which the power transmitting unit is to hold an electrical current level at the transmitter resonator. The power receiving unit of Example 39 also includes a sampler to measure rectifier voltage levels associated with a receiver resonator of the power receiving unit a plurality of times based on the time-to-modulation delay value and the modulation interval duration value to generate a measured charging pattern. The power receiving unit of Example 39 also includes the communication interface to send the measured charging pattern to the power transmitting unit.

In Example 40, the subject matter of Example 39 can optionally include that the communication interface is to send the measured charging pattern to the power transmitting unit by sending separate ones of the measured rectifier voltage levels during separate rectifier voltage reporting intervals.

In Example 41, the subject matter of any one of Examples 39-40 can optionally include that the power receiving unit is a wireless mobile device.

In Example 42, the subject matter of any one of Examples 39-41 can optionally include that the power transmitting unit is a wireless charging station.

In Example 43, the subject matter of any one of Examples 39-42 can optionally include that the communication interface uses a direct, wireless peer-to-peer connection between the power transmitting unit and the power receiving unit to receive the time-to-modulation delay value and the modulation interval duration, and to send the measured charging pattern to the power transmitting unit.

Example 44 is an article of manufacture including computer readable instructions that, when executed, cause a machine to receive a time-to-modulation delay value and a modulation interval duration value at a power receiving unit from a power transmitting unit, the time-to-modulation delay specifying when the power transmitting unit is to start modulating electrical current at a transmitter resonator, and the modulation interval duration specifying a duration for which the power transmitting unit is to hold an electrical current level at the transmitter resonator. The instructions of Example 44 also cause the machine to measure rectifier voltage levels associated with a receiver resonator of the power receiving unit a plurality of times based on the time-to-modulation delay value and the modulation interval duration value to generate a measured charging pattern. The instructions of Example 44 also cause the machine to send the measured charging pattern to the power transmitting unit.

In Example 45, the subject matter of Example 44 can optionally include that the instructions are to cause the machine to send the measured charging pattern to the power transmitting unit by sending separate ones of the measured rectifier voltage levels during separate rectifier voltage reporting intervals.

In Example 46, the subject matter of any one of Examples 44-45 can optionally include that the power receiving unit is a wireless mobile device.

In Example 47, the subject matter of any one of Examples 44-46 can optionally include that the power transmitting unit is a wireless charging station.

In Example 48, the subject matter of any one of Examples 44-47 can optionally include that the instructions are to cause the machine to use a direct, wireless peer-to-peer connection between the power transmitting unit and the power receiving unit to receive the time-to-modulation delay value and the modulation interval duration at the power receiving unit, and to send the measured charging pattern to the power transmitting unit.

Example 49 is a power transmitting unit to detect eligibility of a power receiving unit for wireless charging. The power transmitting unit of Example 49 includes means for receiving a measured charging pattern from the power receiving unit that is in communication with the power transmitting unit. The power transmitting unit of Example 49 also includes means for: determining that the power receiving unit is not eligible for wireless charging by the power transmitting unit when the measured charging pattern does not match a reference charging pattern used to modulate an electrical current at a transmitter resonator of the power transmitting unit, and determining that the power receiving unit is eligible for wireless charging by the power transmitting unit when the measured charging pattern does match the reference charging pattern.

In Example 50, the subject matter of Example 49 can optionally include that the reference charging pattern represents a plurality of high electrical current levels and low electrical current levels.

In Example 51, the subject matter of any one of Examples 49-50 can optionally include means for modulating the electrical current at the transmitter resonator of the power transmitting unit based on the reference charging pattern by applying the high electrical current levels and the low electrical current levels at the transmitter resonator at corresponding intervals of the reference charging pattern.

In Example 52, the subject matter of any one of Examples 49-51 can optionally include means for determining whether the measured charging pattern matches the reference charging pattern based on a threshold number of bits of the measured charging pattern matching corresponding bits of the reference charging pattern.

In Example 53, the subject matter of any one of Examples 49-52 can optionally include means for confirming a cross-connection between the power transmitting unit and the power receiving unit when the measured charging pattern does not match the reference charging pattern.

In Example 54, the subject matter of any one of Examples 49-53 can optionally include that the cross-connection is indicative of the power receiving unit being within wireless communication range of the power transmitting unit but not within wireless charging proximity of the power transmitting unit.

In Example 55, the subject matter of any one of Examples 49-54 can optionally include means for sending a time-to-modulation delay value and a modulation interval duration value to the power receiving unit, the time-to-modulation delay value to inform the power receiving unit when to begin measuring a rectifier voltage level associated with a receiving resonator of the power receiving unit, and the modulation interval duration value to inform the power receiving unit of interval durations at which to perform measurements of the rectifier voltage level.

In Example 56, the subject matter of any one of Examples 49-55 can optionally include that the means for receiving the measured charging pattern is to receive the measured charging pattern by receiving a plurality of separate rectifier voltage measurement values from the power receiving unit at corresponding reporting intervals, the separately received rectifier voltage measurement values forming the measured charging pattern.

In Example 57, the subject matter of any one of Examples 49-56 can optionally include that the power receiving unit is a wireless mobile device.

In Example 58, the subject matter of any one of Examples 49-57 can optionally include that the power transmitting unit is a wireless charging station.

In Example 59, the subject matter of any one of Examples 49-58 can optionally include that the means for receiving the measured charging pattern is to use a direct, wireless peer-to-peer connection between the power transmitting unit and the power receiving unit to receive the measured charging pattern from the power receiving unit.

Example 60 is a power receiving unit to measure a charging pattern. The power receiving unit of Example 60 includes means for receiving a time-to-modulation delay value and a modulation interval duration value at the power receiving unit from a power transmitting unit, the time-to-modulation delay specifying when the power transmitting unit is to start modulating electrical current at a transmitter resonator, and the modulation interval duration specifying a duration for which the power transmitting unit is to hold an electrical current level at the transmitter resonator. The power receiving unit of Example 60 also includes means for measuring rectifier voltage levels associated with a receiver resonator of the power receiving unit a plurality of times based on the time-to-modulation delay value and the modulation interval duration value to generate a measured charging pattern. The power receiving unit of Example 60 also includes means for sending the measured charging pattern to the power transmitting unit.

In Example 61, the subject matter of Example 60 can optionally include that the means for sending the measured charging pattern to the power transmitting unit is to send the measured charging pattern by sending separate ones of the measured rectifier voltage levels during separate rectifier voltage reporting intervals.

In Example 62, the subject matter of any one of Examples 60-61 can optionally include that the power receiving unit is a wireless mobile device.

In Example 63, the subject matter of any one of Examples 60-62 can optionally include that the power transmitting unit is a wireless charging station.

In Example 64, the subject matter of any one of Examples 60-63 can optionally include that the means for receiving a time-to-modulation delay value and a modulation interval duration value uses a direct, wireless peer-to-peer connection between the power transmitting unit and the power receiving unit.

Although certain example methods, apparatus and articles of manufacture have been disclosed herein, the scope of coverage of this patent is not limited thereto. On the contrary, this patent covers all methods, apparatus and articles of manufacture fairly falling within the scope of the claims of this patent.

What is claimed is:

1. A method to detect eligibility for wireless charging at a power transmitting unit, the method comprising:
receiving a measured charging pattern from a power receiving unit that is in communication with the power transmitting unit;
when the measured charging pattern does not match a reference charging pattern used to modulate an electrical current at a transmitter resonator of the power transmitting unit, determining that the power receiving unit is not eligible for wireless charging by the power transmitting unit; and
when the measured charging pattern does match the reference charging pattern, determining that the power receiving unit is eligible for wireless charging by the power transmitting unit.

2. A method of claim 1, wherein the reference charging pattern represents a plurality of high electrical current levels and low electrical current levels.

3. A method of claim 2, further including modulating the electrical current at the transmitter resonator of the power transmitting unit based on the reference charging pattern by applying the high electrical current levels and the low electrical current levels at the transmitter resonator at corresponding intervals of the reference charging pattern.

4. A method of claim 1, wherein determining whether the measured charging pattern matches the reference charging pattern includes determining whether the measured charging pattern sufficiently matches the reference charging pattern within a threshold.

5. A method of claim 1, further including confirming a cross-connection between the power transmitting unit and the power receiving unit when the measured charging pattern does not match the reference charging pattern.

6. A method of claim 5, wherein the cross-connection is indicative of the power receiving unit being within wireless communication range of the power transmitting unit but not within wireless charging proximity of the power transmitting unit.

7. A method of claim 1, further including sending a time-to-modulation delay value and a modulation interval duration value from the power transmitting unit to the power receiving unit, the time-to-modulation delay value to inform the power receiving unit when to begin measuring a rectifier voltage level associated with a receiving resonator of the power receiving unit, and the modulation interval duration value to inform the power receiving unit of interval durations at which to perform measurements of the rectifier voltage level.

8. A method of claim 1, wherein receiving the measured charging pattern from the power receiving unit includes receiving a plurality of separate rectifier voltage measurement values from the power receiving unit at corresponding reporting intervals, the separately received rectifier voltage measurement values forming the measured charging pattern.

9. A method of claim 1, wherein the power receiving unit is a wireless mobile device.

10. A method of claim 1, wherein the power transmitting unit is a wireless charging station.

11. A method of claim 1, wherein the measured charging pattern is received from the power receiving unit using a direct, wireless peer-to-peer connection between the power transmitting unit and the power receiving unit.

12. A power transmitting unit to detect eligibility of a power receiving unit for wireless charging, the power transmitting unit comprising:
a communication interface to receive a measured charging pattern from the power receiving unit that is in communication with the power transmitting unit; and
a processor to:
determine that the power receiving unit is not eligible for wireless charging by the power transmitting unit when the measured charging pattern does not match a reference charging pattern used to modulate an electrical current at a transmitter resonator of the power transmitting unit; and
determine that the power receiving unit is eligible for wireless charging by the power transmitting unit when the measured charging pattern does match the reference charging pattern.

13. A power transmitting unit of claim 12, wherein the reference charging pattern represents a plurality of high electrical current levels and low electrical current levels.

14. A power transmitting unit of claim 13, further including a power amplifier to modulate the electrical current at the transmitter resonator of the power transmitting unit based on the reference charging pattern by applying the high electrical current levels and the low electrical current levels at the transmitter resonator at corresponding intervals of the reference charging pattern.

15. A power transmitting unit of claim 12, further including a comparator to determine whether the measured charging pattern matches the reference charging pattern based on a threshold number of bits of the measured charging pattern matching corresponding bits of the reference charging pattern.

16. A power transmitting unit of claim 12, wherein the processor is further to confirm a cross-connection between the power transmitting unit and the power receiving unit when the measured charging pattern does not match the reference charging pattern.

17. A power transmitting unit of claim 16, wherein the cross-connection is indicative of the power receiving unit being within wireless communication range of the power transmitting unit but not within wireless charging proximity of the power transmitting unit.

18. A power transmitting unit of claim 12, wherein the communication interface is further to send a time-to-modulation delay value and a modulation interval duration value to the power receiving unit, the time-to-modulation delay value to inform the power receiving unit when to begin measuring a rectifier voltage level associated with a receiving resonator of the power receiving unit, and the modulation interval duration value to inform the power receiving unit of interval durations at which to perform measurements of the rectifier voltage level.

19. A power transmitting unit of claim 12, wherein the communication interface is to receive the measured charging pattern from the power receiving unit by receiving a plurality of separate rectifier voltage measurement values from the power receiving unit at corresponding reporting intervals, the separately received rectifier voltage measurement values forming the measured charging pattern.

20. A power transmitting unit of claim 12, wherein the power receiving unit is a wireless mobile device.

21. A power transmitting unit of claim 12, wherein the power transmitting unit is a wireless charging station.

22. A power transmitting unit of claim 12, wherein the communication interface is to use a direct, wireless peer-to-peer connection between the power transmitting unit and the power receiving unit to receive the measured charging pattern from the power receiving unit.

23. An article of manufacture comprising computer readable instructions that, when executed, cause a machine to at least:
receive a measured charging pattern from a power receiving unit that is in communication with a power transmitting unit;
determine that the power receiving unit is not eligible for wireless charging by the power transmitting unit when the measured charging pattern does not match a reference charging pattern used to modulate an electrical current at a transmitter resonator of the power transmitting unit; and
determine that the power receiving unit is eligible for wireless charging by the power transmitting unit when the measured charging pattern does match the reference charging pattern.

24. An article of manufacture of claim 23, wherein the reference charging pattern represents a plurality of high electrical current levels and low electrical current levels.

25. An article of manufacture of claim 24, wherein the instructions are to further cause the machine to modulate the electrical current at the transmitter resonator of the power transmitting unit based on the reference charging pattern by applying the high electrical current levels and the low electrical current levels at the transmitter resonator at corresponding intervals of the reference charging pattern.
